(19) United States
(12) Patent Application Publication
(10) Pub. No.: US 2024/0075579 A1
(43) Pub. Date: Mar. 7, 2024

(54) SURFACE PROPERTY MEASURING APPARATUS FOR POLISHING PAD, SURFACE PROPERTY MEASURING METHOD FOR POLISHING PAD, AND SURFACE PROPERTY JUDGING METHOD FOR POLISHING PAD

(71) Applicant: EBARA CORPORATION, Tokyo (JP)

(72) Inventors: Kohei OHSHIMA, Tokyo (JP); Hisanori MATSUO, Tokyo (JP); Toshifumi KIMBA, Tokyo (JP); Nobuyuki TAKADA, Tokyo (JP)

(21) Appl. No.: 18/272,941

(22) PCT Filed: Jan. 5, 2022
(86) PCT No.: PCT/JP22/00075

§ 371 Date: Jul. 18, 2023

(30) Foreign Application Priority Data
Jan. 21, 2021 (JP) 2021-007904

(51) Int. Cl. B24B 37/005

(52) U.S. Cl. CPC B24B 37/005

(57) ABSTRACT

The present invention relates to a surface property measuring apparatus for a polishing pad used for polishing a substrate, such as a semiconductor wafer, a surface property measuring method for a polishing pad, and a surface property judging mehod for a polishing pad. The surface property measuring apparatus (30) includes: a light-emitting structure (32) configured to irradiate the polishing pad (2) with light from a plurality of directions as viewed from a polishing surface (2a) of the polishing pad (2); and a light-receiving structure (32) configured to receive reflected light traveling in a plurality of directions from the surface of the polishing pad (2).

### TECHNICAL FIELD

The present invention relates to a surface property measuring apparatus for a polishing pad used for polishing a substrate, such as a semiconductor wafer, a surface property measuring method for a polishing pad, and a surface property judging method for a polishing pad.

### BACKGROUND ART

With a recent trend toward higher integration and higher density in semiconductor devices, circuit interconnects become finer and finer and the number of levels in multilayer interconnect is increasing. In the process of achieving the multilayer interconnect structure with finer interconnects, film coverage of step geometry (or step coverage) is lowered through thin film formation as the number of interconnect levels increases, because surface steps grow while following surface irregularities on a lower layer. Therefore, in order to fabricate the multilayer interconnect structure, it is necessary to improve the step coverage and planarize the surface in an appropriate process. Further, since finer optical lithography entails shallower depth of focus, it is necessary to planarize surfaces of semiconductor device so that irregularity steps formed thereon fall within a depth of focus in optical lithography.

Accordingly, in a manufacturing process of the semiconductor devices, a planarization technique for a surface of the semiconductor device is becoming more important. The most important technique in this surface planarization is chemical mechanical polishing (CMP). This chemical mechanical polishing is a process of polishing a substrate, such as a wafer, by placing the substrate in sliding contact with a polishing surface of a polishing pad while supplying a polishing liquid onto the polishing surface. The polishing liquid is slurry containing abrasive grains, such as silica (SiO₂) or ceria (CeO₂).

A polishing apparatus for performing CMP (Chemical Mechanical Polishing) described above includes a polishing table having a polishing pad and a substrate holding device called a polishing head for holding a semiconductor wafer (substrate). The polishing apparatus is configured to polish an insulating film, a metal film, or the like on the substrate by pressing the substrate against the polishing pad with a predetermined pressure while holding the substrate by the substrate holding device.

When the substrate is polished, the abrasive grains and polishing debris adhere to the surface of the polishing pad, and the surface shape and condition of the polishing pad change, resulting in deterioration of polishing performance. As a result, as polishing of substrate is repeated, a polishing rate decreases and uneven polishing occurs. Therefore, in order to repair the surface shape and condition of the deteriorated polishing pad, dressing (conditioning) of the polishing pad is performed using a dresser.

The surface shape and condition of the polishing pad, i.e., a surface property of the polishing pad is one of factors that determine the CMP performance. Therefore, it is desirable to directly measure the surface property of the polishing pad and reflect a measured value of the polishing pad in the dressing condition. Therefore, in a conventional polishing apparatus, a device for directly measuring the surface property of the polishing pad is used to determine the dressing condition. In this specification, a device for measuring a surface property of a polishing pad is referred to as a “surface property measuring apparatus”.

### CITATION LIST

### Patent Literature

Patent document 1: International Patent Publication No. WO 2016/111335

Patent document 2: Japanese laid-open patent publication No. 2015-174156

Patent document 3: Japanese laid-open patent publication No. 2019-19370

### SUMMARY OF INVENTION

### Technical Problem

Recently, from a viewpoint of evaluating a surface condition of the polishing pad in more detail and optimizing the dressing condition, there is an increasing demand for measuring the surface property of the polishing pad with higher accuracy. In addition, from a viewpoint of extending a life of the dresser by preventing excessive dressing and reducing consumables, such as slurry used for polishing a substrate, there is an increasing demand for accurately judging the surface property of the polishing pad.

Accordingly, an object of the present invention is to provide a surface property measuring apparatus for a polishing pad and a surface property measuring method for a polishing pad capable of improving accuracy of measuring a surface property of a polishing pad. An object of the present invention is to provide a method capable of accurately judging a surface property of a polishing pad.

### Solution to Problem

In an embodiment, there is provided a surface property measuring apparatus for a polishing pad used for polishing a substrate, comprising: a light-emitting structure configured to irradiate the polishing pad with light from a plurality of directions as viewed from a polishing-surface side of the polishing pad; and a light-receiving structure configured to receive reflected light traveling in a plurality of directions from the surface of the polishing pad.

In an embodiment, the surface property measuring apparatus further comprises an irradiating-direction changing mechanism configured to change an irradiating direction of the light.

In an embodiment, the irradiating-direction changing mechanism comprises a rotating motor configured to rotate the light-emitting structure and the light-receiving structure, and a shaft coupled to the rotating motor.

In an embodiment, the light-emitting structure includes a plurality of light sources facing in different directions; and the light-receiving structure includes a plurality of light-receiving elements facing in different directions.

In an embodiment, the surface property measuring apparatus further comprises a data processing device electrically coupled to the light-receiving structure, the data processing device being configured to determine an index value based on intensity distributions of a plurality of reflected lights from the polishing pad corresponding to a plurality of lights irradiating the polishing pad from different directions, the index value indirectly indicating a surface property of the polishing pad.

In an embodiment, there is provided a surface property measuring method for a polishing pad, comprising: irradiating the polishing pad with a plurality of lights from different irradiating directions as viewed from a polishing-surface side of the polishing pad; receiving a plurality of reflected lights from the polishing pad corresponding respectively to the plurality of lights irradiating the polishing pad; obtaining intensity distributions of the plurality of reflected lights; and determining an index value based on the intensity distributions, the index value indirectly indicating a surface property of the polishing pad.

In an embodiment, irradiating the polishing pad with the plurality of lights from the different irradiating directions comprises irradiating the polishing pad with light while changing an irradiating direction of the light; and receiving the plurality of reflected lights from the polishing pad comprises receiving the plurality of reflected lights from the polishing pad corresponding to lights irradiating the polishing pad from different irradiating directions.

In an embodiment, irradiating the polishing pad with the plurality of lights from the different irradiating directions comprises irradiating the polishing pad with the plurality of lights from a plurality of irradiating directions, the plurality of lights being emitted by a plurality of light sources; and receiving the plurality of reflected lights from the polishing pad comprises receiving, by a plurality of light-receiving elements, the plurality of reflected lights from the polishing pad corresponding to the plurality of lights irradiating the polishing pad from the plurality of irradiating directions.

In an embodiment, there is provided a surface property judging method for a polishing pad, comprising: irradiating a plurality of points on a surface of the polishing pad with laser light; receiving a plurality of reflected lights from the surface of the polishing pad; determining intensity distributions of the plurality of reflected lights at the plurality of points on the surface of the polishing pad; calculating a wavelength composition ratio from the intensity distributions determined at the plurality of points, the wavelength composition ratio indirectly indicating a surface property of the polishing pad; judging whether the surface property of the polishing pad is good or not based on the wavelength composition ratio.

In an embodiment, calculating the wavelength composition ratio from the intensity distributions determined at the plurality of points comprises calculating wavelength composition ratios from the intensity distributions, respectively.

In an embodiment, calculating the wavelength composition ratio from the intensity distributions determined at the plurality of points comprises: calculating an average of the intensity distributions; and calculating the wavelength composition ratio from the average of the intensity distributions.

In an embodiment, judging whether the surface property of the polishing pad is good or not based on the wavelength composition ratio comprises: determining whether the wavelength composition ratios are within a predetermined reference range; and judging that the surface property of the polishing pad is good when all of the wavelength composition ratios are within the predetermined reference range.

In an embodiment, judinng whether the surface property of the polishing pad is good or not based on the wavelength composition ratio comprises: calculating an average of the wavelength composition ratios; comparing the average with a predetermined threshold value; determining whether the wavelength composition ratios are within a predetermined reference range; and judging that the surface property of the polishing pad is good when the average is smaller than the threshold value and all of the wavelength composition ratios are within the predetermined reference range.

In an embodiment, judging whether the surface property of the polishing pad is good or not based on the wavelength composition ratio comprises: calculating an average of the wavelength composition ratios; comparing the average with a predetermined threshold value; determining whether the wavelength composition ratios are within a predetermined reference range; and judging that the surface property of the polishing pad is good when the average is larger than the threshold value and all of the wavelength composition ratios are within the predetermined reference range.

In an embodiment, the surface property judging method further comprises terminating a break-in process of the polishing pad when the surface property of the polishing pad is determined to be good.

### Advantageous Effects of Invention

According to the present invention, the intensity distributions of the reflected lights from the polishing pad corresponding to the lights directed to the polishing pad in different directions can be obtained. As a result, the measurement accuracy of the surface property of the polishing pad can be improved. Furthermore, according to the present invention, the intensity distributions of the reflected lights from the polishing pad at a plurality of points on the surface of the polishing pad axe obtained. As a result, the surface property of the polishing pad including in-plane variations can be evaluated. Accordingly, the surface property of the polishing pad can be judged with high accuracy.

### BRIEF DESCRIPTION OF DRAWINGS

FIG. 1 is a schematic diagram showing an embodiment of a polishing apparatus including a surface property measuring apparatus for a polishing pad;

FIG. 2 is a schematic diagram showing an embodiment of an internal structure (measuring structure) of a measuring head;

FIG. 3 is a schematic diagram showing another embodiment of the internal structure of the measuring head;

FIG. 4 is a diagram explaining reflected light from a polishing pad;

FIG. 5 is a schematic diagram showing a spatial wavelength spectrum of a surface of the polishing pad;

FIG. 6 is a perspective view schematically showing an embodiment in which the measuring head is arranged at a measuring position;

FIG. 7A is a front view of the measuring head;

FIG. 7B is a bottom view of the measuring head;

FIG. 8 is an enlarged schematic diagram showing the measuring head and its surroundings shown FIG. 6;

FIG. 9 is a flow chart showing an embodiment of a surface property judging method;

FIG. 10 is a diagram showing an example of multiple measurement points on the surface of the polishing pad;

FIG. 11 is a graph showing an example of wavelength composition ratios under each processing condition of the polishing pad during break-in process;

FIG. 12A is a diagram comparing the wavelength composition ratios under a condition 1 in FIG. 11 with a predetermined reference range and a predetermined threshold value;

FIG. 12B is a diagram comparing the wavelength composition ratios under a condition 6 in FIG. 11 with a predetermined reference range and a predetermined threshold value;

FIG. 12C is a diagram comparing the wavelength composition ratios under a condition 10 in FIG. 11 with a predetermined reference range and a predetermined threshold value;

FIG. 13 is a flow chart showing another embodiment of a surface property judging method;

FIG. 14 is a diagram showing results of measuring the surface property of the polishing pad 2 after dressing of the polishing pad is performed under predetermined dressing condition while the substrate W is polished, and calculating the wavelength composition ratios;

FIG. 15 is a schematic diagram showing another embodiment of the surface property measuring apparatus;

FIG. 16 is a diagram showing a light-emitting structure and a light-receiving structure when rotating around an axis;

FIG. 17 is a flow chart showing an embodiment of a surface property measuring method for the polishing pad;

FIG. 18 is a graph showing an intensity distribution of reflected light from the polishing pad when an irradiating angle is 0°;

FIG. 19 is a graph showing an intensity distribution of reflected light from the polishing pad when the irradiating angle is 45°;

FIG. 20 is a graph showing the intensity distribution of reflected light from the polishing pad when the irradiating angle is 90°;

FIG. 21 is a graph showing the intensity distribution of reflected light from the polishing pad when the irradiating angle is 135°;

FIG. 22 is a graph showing the intensity distribution of reflected light from the polishing pad when the irradiating angle is 180°;

FIG. 23 is a graph showing the intensity distribution of reflected light from the polishing pad when the irradiating angle is 225°;

FIG. 24 is a graph showing the intensity distribution of reflected light from the polishing pad when the irradiating angle is 270°;

FIG. 25 is a graph showing the intensity distribution of reflected light from the polishing pad when the irradiating angle is 315°;

FIG. 26 is a schematic diagram showing still another embodiment of the surface property measuring apparatus; and

FIG. 27 is a top view of a measuring head shown in FIG. 26.

### DESCRIPTION OF EMBODIMENTS

Hereinafter, embodiments of the present invention will be described with reference to the drawings. In the drawings described below, the same or corresponding components are denoted by the same reference numerals, and repetitive descriptions are omitted.

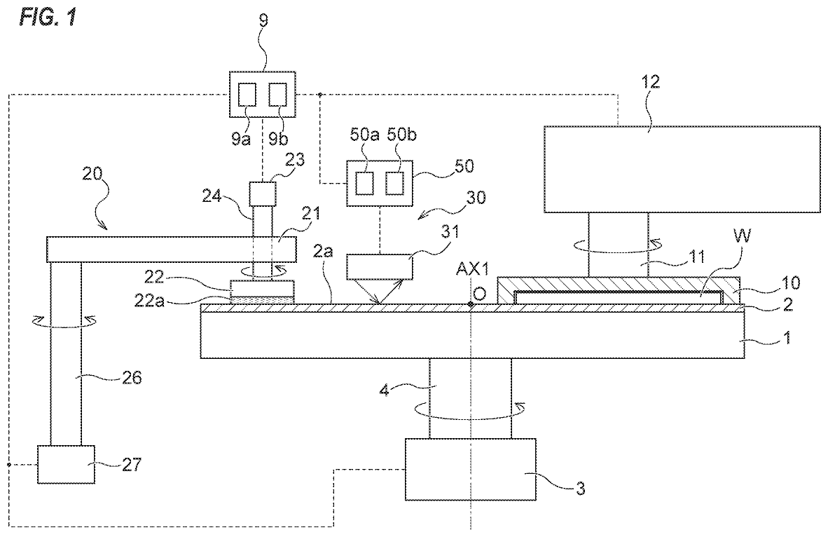

FIG. 1 is a schematic diagram showing an embodiment of a polishing apparatus including a surface property measuring apparatus for a polishing pad. As shown in FIG. 1, the polishing apparatus (CMP apparatus) includes a polishing table 1 configured to support a polishing pad 2, a polishing head 10 configured to hold a substrate W which is an object to be polished (e.g., a semiconductor wafer) and press the substrate W against the polishing pad on the polishing table, a dressing device 20 configured to dress the polishing pad 2, a surface property measuring apparatus 30 configured to measure a surface property of the polishing pad 2, such as a surface shape and a surface condition of the polishing pad 2, and an operation controller 9 configured to control operations of each component of the polishing apparatus.

The polishing table 1 is coupled via a table shaft 4 to a table rotating motor 3 disposed below the polishing table 1. The polishing table 1 is rotatable about an axis AX1 of the table shaft 4. The polishing pad 2 is attached to an upper surface of the polishing table 1, and a surface of the polishing pad 2 constitutes a polishing surface 2a for polishing the substrate W. The polishing pad 2 is attached to the polishing table 1 such that a center O of the polishing pad 2 is on the axis AX1. A polishing-liquid supply nozzle (not shown) is installed above the polishing table 1, and a polishing liquid (slurry) is supplied onto the polishing pad 2 on the polishing table 1 by the polishing-liquid supply nozzle.

The polishing head 10 is coupled to a polishing-head shaft 11, and the polishing-head shaft 11 is vertically movable with respect to a polishing-head oscillation arm 12 by an elevating mechanism (not shown). The elevating mechanism is coupled to the polishing-head oscillation arm 12. When the polishing-head shaft 11 is moved up and down, the entire polishing head 10 is moved up and down with respect to the polishing-head oscillation arm 12, and positioning of the polishing head 10 is achieved. The polishing-head shaft 11 is rotated by a polishing-head rotating motor (not shown), so that the polishing head 10 rotates around an avis of the polishing-head shaft 11. In one embodiment, the polishing-head rotating motor may be located within the polishing-head oscillation arm 12.

As shown in FIG. 1, the polishing head 10 is configured to be able to hold the substrate W, such as a semiconductor wafer, on its lower surface. The polishing-head oscillation arm 12 is configured to swing, so that the polishing head 10 holding the substrate W on its lower surface can be moved from a substrate receiving position to a position above the polishing table 1 by the swing motion of the polishing-head oscillation arm 12. The polishing head 10, holding the substrate W on its lower surface, presses the substrate W against the surface (polishing surface 2a) of the polishing pad 2. The polishing table 1 and the polishing head 10 are rotated, and the polishing liquid (slurry) is supplied onto the polishing pad 2 from the polishing-liquid supply nozzle (not shown) provided above the polishing table 1. The polishing liquid used in this embodiment contains silica (SiO₂) or ceria (CeO₂) as abrasive grains. In this way, while the polishing liquid is being supplied onto the polishing pad 2, the substrate W is pressed against the polishing pad 2, and the substrate W and the polishing pad 2 are moved relative to each other, so that an insulating film, a metal film, etc. on the substrate is polished. An example of the insulating film includes SiO₂. Examples of the metal film include Cu film, W film, Ta film, and Ti film.

The dressing device 20 includes a dresser 22 configured to rub against the polishing surface 2a of the polishing pad 2, a dresser shaft 24 coupled to the dresser 22, an air cylinder 23 provided at an upper end of the dresser shaft 24, and a dresser arm 21 that rotatably supports the dresser shaft 24. A lower part of the dresser 22 is composed of a dressing member 22a. The dressing member 22a has a circular dressing surface, and hard particles are fixed to the dressing surface by electrodeposition or the like. Examples of hard particles include diamond particles and ceramic particles.

A dresser rotating motor (not shown) is arranged in the dresser arm 21. The dresser shaft 24 is rotated by the dresser rotating motor, so that the dresser 22 is rotated around an axis of the dresser shaft 24 by the rotation of the dresser shaft 24. The air cylinder 23 vertically moves the dresser shaft 24 and the dresser 22 together to press the dressing member 22a against the polishing surface 2a of the polishing pad 2 with a predetermined pressing force.

The air cylinder 23 is coupled to a gas supply source (not shown) and is configured to apply a dressing load on the polishing pad 2 to the dresser 22. The dressing load can be regulated by air pressure supplied into the air cylinder 23. Furthermore, the air cylinder 23 can move the dresser 22 away from the polishing surface 2a of the polishing pad 2. The air cylinder 23 functions as an elevating actuator that vertically moves the dresser shaft 24 and the dresser 22 relative to the dresser arm 21. In one embodiment, a combination of a servomotor and a ball screw mechanism may be used as the elevating actuator that moves the dresser shaft 24 and dresser 22 up and down relative to the dresser arm 21.

The dressing device 20 further includes a support shaft 26 coupled to the dresser arm 21, and a support-shaft rotating motor (rotating actuator) 27 configured to rotate the support shaft 26. When the support-shaft rotating motor 27 is in motion, the dresser arm 21 rotates about the support shaft 26.

The dressing of the polishing surface 2a of the polishing pad 2 is performed as follows. The polishing table 1 and the polishing pad 2 are rotated by the table rotating motor 3, and a dressing liquid (for example, pure water) is supplied onto the polishing surface 2a of the polishing pad 2 from a dressing-liquid supply nozzle (not shown). In this state, the dresser 22 is rotated around the axis of the dresser shaft 24. The dresser 22 is pressed against the polishing surface 2a by the air cylinder 23, so that the lower surface of the dressing member 22a is placed in sliding contact with the polishing surface 2a in the presence of the dressing liquid on the polishing surface 2a. While the dresser 22 is rotating, the dresser arm 21 swings (or oscillates) around the support shaft 26 to move the dresser 22 in a radial direction of the polishing surface 2a. In this manner, the polishing pad 2 is scraped off by the dresser 22, and the polishing surface 2a is dressed (regenerated). The polishing pad 2 has a fine uneven structure in its polishing surface 2a. As the polishing of the substrate W progresses, raised portions of the uneven structure collapse. The dressing operation can regenerate the raised portions in an upright state.

The operation controller 9 includes a memory 9a storing programs therein, and a processor 9b configured to execute arithmetic operations according to instructions included in the programs. The processor 9b includes a CPU (Central Processing Unit) or GPU (Graphic Processing Unit) that performs arithmetic operations according to the instructions included in the programs stored in the memory 9a. The memory 9a comprises a main memory (e.g., random access memory) accessible by the processor 9b and an auxiliary memory (e.g., hard disk drive or solid state drive) for storing data and programs. The operation controller 9 is composed of at least one computer.

The table rotating motor 3, the elevating mechanism (not shown), the polishing-head rotating motor (not shown), the polishing-liquid supply nozzle (not shown), the dressing device 20, and the surface property measuring apparatus 30 are electrically coupled to the operation controller 9, and the operations of these components are controlled by the operation controller 9.

The surface property measuring apparatus 30 for the polishing pad includes a measuring head 31 and a data processing device 50 electrically coupled to the measuring head 31. The surface property measuring apparatus 30 is configured to measure the pad surface property by irradiating the polishing pad 2 with light and receiving reflected light from the surface (polishing surface 2a) of the polishing pad 2.

The data processing device 50 includes a memory 50a storing programs therein, and a processor 50b configured to execute arithmetic operations according to instructions included in the programs. The processor 50b includes a CPU (Central Processing Unit) or GPU (Graphic Processing Unit) that performs arithmetic operations according to the instructions included in the programs stored in the memory 50a. The memory 50a includes a main memory (e.g., random access memory) accessible by the processor 50b and auxiliary memory (e.g., hard disk drive or solid state drive) for storing data and the programs. The data processing device 50 is composed of at least one computer. In one embodiment, the operation controller 9 and the data processing device 50 may be an integrated structure.

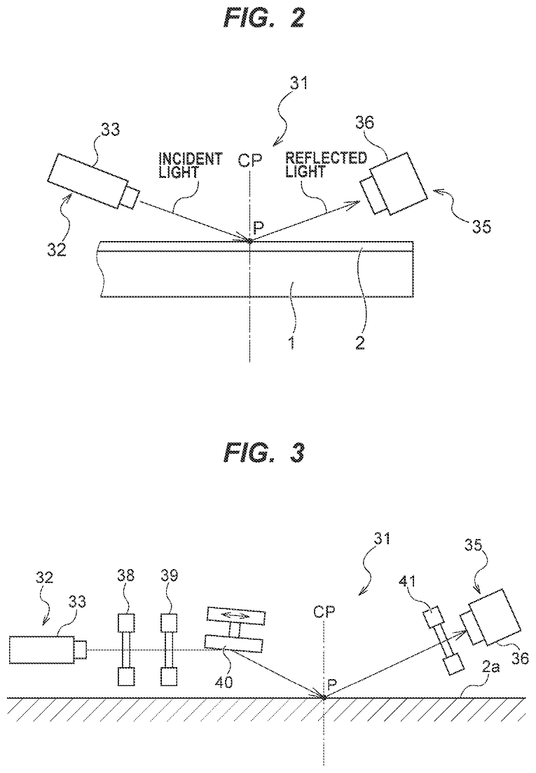

FIG. 2 is a schematic diagram showing an embodiment of internal structures (measuring structures) of the measuring head 31. As shown in FIG. 2, the measuring head 31 includes a light-emitting structure 32 configured to irradiate the polishing pad 2 with light, and a light-receiving structure 35 configured to receive reflected light from the surface (polishing surface 2a) of the polishing pad 2. The light-emitting structure 32 includes a light source 33 configured to emit the light. An example of the light emitted by the light source 33 is laser light. In this embodiment, the light source 33 is a laser light source configured to emit the laser light. The laser light is applied to an irradiation position P on the polishing surface 2a.

The light-receiving structure 35 has a light-receiving element 36. The light-receiving element 36 may be a linear (one-dimensional) charge-coupled device (CCD) having a dimension capable of receiving 0th-order diffracted light to n-order diffracted light (e.g., 4th-order diffracted light or 7th-order diffracted light) of the reflected light from the polishing pad 2. Alternatively, the light-receiving element 36 may be a complementary metal oxide semiconductor (CMOS) device. The light-receiving element 36 has a large number of light-receiving pixels, and is configured to be able to detect an intensity of the reflected light at each pixel. The light-emitting structure 32 and the light-receiving structure 35 are electrically coupled to the data processing device 50.

FIG. 3 is a schematic diagram showing another embodiment of the internal structures of the measuring head 31. Configurations and operations of the present embodiment, which are not specifically described, are the same as those of the embodiments described with reference to FIG. 2, and repetitive descriptions thereof will be omitted. As shown in FIG. 3, the measuring head 31 of this embodiment includes a polarizer 38, an ND filter (neutral density filter) 39, and a mirror 40, which are sequentially arranged along an optical path of the laser light emitted by the light-emitting structure 32. The mirror 40 is configured to change the optical path by reflecting the laser light emitted by the light-emitting structure 32. A light-reducing filter 41 is arranged in front of the light-receiving structure 35 in the optical path of the reflected light from the surface of the polishing pad 2.

The laser light emitted by the light-emitting structure 32 is S-polarized by the polarizer 38, and then a quantity of the light is regulated by the ND filter 39. The laser light is then incident on the mirror 40 whose angle is adjusted in advance. The laser light is reflected by the mirror 40 to change its optical path, and is incident on the surface of the polishing pad 2. The reflected light from the surface of the polishing pad 2 passes through the light-reducing filter 41 and is received by the light-receiving structure 33. In one embodiment, instead of the light-reducing filter 41, a bandpass filter that allows transmission of only a specific wavelength band may be arranged.

According to this embodiment, a reflectance on the surface of the polishing pad 2 can be improved by causing the laser light emitted by the light source 33 to be S-polarized by the polarizer 38 and then directing the S-polarized laser light to the polishing pad 2. In one embodiment, a band-pass filter may be provided to pass only reflected light having wavelength(s) within a range of ±5 nm with respect to a wavelength of the laser light emitted by the light source 33. This makes it possible to reduce an influence of ambient light that may cause noise. In this embodiment, laser light having a wavelength of 650 nm is used as the laser light emitted by the light source 33.

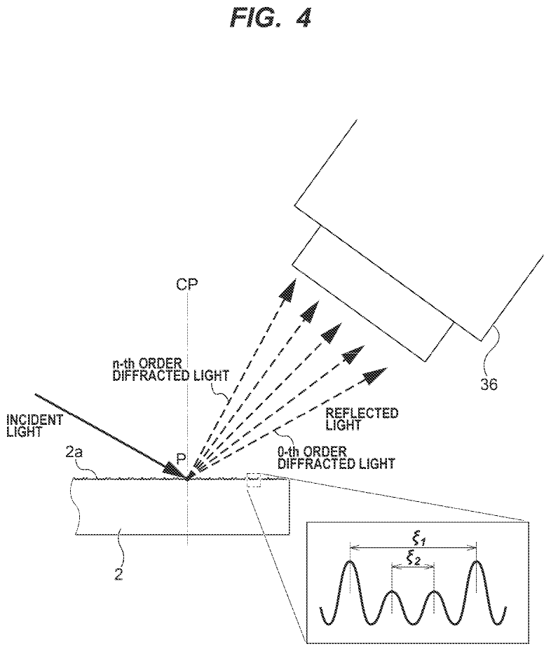

FIG. 4 is a diagram fir explaining the reflected light from the polishing pad 2. As described above, the polishing pad 2 has fine uneven structures in the polishing surface 2a, and the surface shape of the polishing pad 2 can be regarded as a superposition of simple (single-wavelength) spatial waveforms. In the example shown in FIG. 4, the surface (polishing surface 2a) of the polishing pad 2 has a spatial waveform of a wavelength ξ₁ and a spatial waveform of a wavelength ξ₂. The reflected light from the polishing pad 2 includes scattered light from the 0th order diffracted light to the nth order diffracted light according to the wavelength (spatial wavelength) of each spatial waveform of the polishing surface 2a. The light-receiving element 36 acquires an intensity distribution of the reflected light by receiving the reflected light including the scattered light. The intensity distribution of the reflected light is a distribution of intensities of the received light at respective light receiving positions in the light-receiving element 36. The light-receiving element 36 is configured to receive lights of spatial wavelengths that are different for pixels. The spatial wavelength of light received by each pixel can be calculated from the position of each pixel. Therefore, the intensity distribution of the reflected light acquired by the light-receiving element 36 can be said to be an intensity distribution of the spatial wavelength (or spatial frequency).

Next, a method of measuring the surface property of the polishing pad 2 will be described. First, the surface of the polishing pad 2 is irradiated with the laser light emitted by the light source 33. The light-receiving element 36 measures information on the surface of the polishing pad 2 by receiving the laser light reflected by the surface of the polishing pad 2. Specifically, the light-receiving element 36 acquires the intensity distribution of reflected light from the polishing pad 2. The intensity distribution of the reflected light is transmitted to the data processing device 50. Next, the data processing device 50 converts the intensity distribution of the reflected light into a spatial wavelength spectrum of the surface of the polishing pad 2 by performing Fourier transform on the intensity distribution of the reflected light. Furthermore, the data processing device 50 calculates, from the spatial wavelength spectrum, an index value that indirectly indicates the surface property of the polishing pad 2, and transmits the calculated index value to the operation controller 9. The operation controller 9 determines dressing condition and judges the surface property of the polishing pad 2 based on the index value received. In one embodiment, the operation controller 9 may detect insufficient dressing or may determine an end of dressing by judging the surface property of the polishing pad 2.

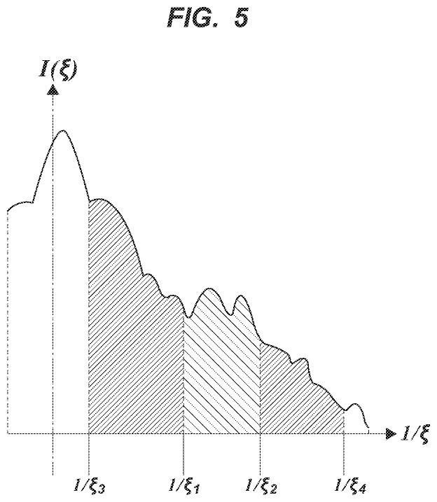

FIG. 5 is a schematic diagram showing the spatial wavelength spectrum of the surface of the polishing pad 2. Vertical axis in FIG. 5 represents intensity I(ξ) of the reflected light obtained by the light-receiving element 36, and horizontal axis represents spatial frequency. Spatial frequencies 1/ξ₁ to 1/ξ₄ are reciprocals of spatial wavelengths ξ₁ to ξ₄.

As described above, the data processing device 50 calculates the index value that indirectly indicates the surface property of the polishing pad 2 from the intensity distribution of the reflected light from the polishing pad 2. An example of the index value is a wavelength composition ratio. In this specification, the wavelength composition ratio is defined as a ratio of an integrated value of intensities of the reflected light (hereinafter which may be referred to as reflection intensities) in a predetermined spatial wavelength region to an integrated value of reflection intensities in a wider spatial wavelength region including the predetermined spatial wavelength region. The larger the wavelength composition ratio, the greater the intensities of the reflected light in the predetermined spatial wavelength region. This means that the measured surface of the polishing pad 2 contains more predetermined spatial wavelength components. Since it has been investigated in advance that the number of predetermined spatial wavelength components has a strong relationship with the CMP performance, the wavelength composition ratio enables the estimation of the CMP performance. Selecting an appropriate spatial wavelength region depending on a process makes it possible to obtain the wavelength composition ratio as the surface property of the polishing pad 2 which has a strong relationship with the CMP performance.

For example, in FIG. 5, the wavelength composition ratio of the reflection intensities in the spatial wavelength region from the spatial frequency 1/ξ₁ (i.e., spatial wavelength ξ₁) to the spatial frequency 1/ξ₂ (i.e., the spatial wavelength ξ₂) to the reflection intensities in the spatial wavelength region from the spatial frequency 1/ξ₃ (i.e., spatial wavelength ξ₃) to the spatial frequency 1/ξ₄ (i.e., the spatial wavelength ξ₄) is determined by the following formula (1).

$$\frac{{\int }_{{ξ}_{1}}^{{ξ}_{2}} I ( ξ ) d ξ}{{\int }_{{ξ}_{3}}^{{ξ}_{4}} I ( ξ ) d ξ} \times 100 [ \% ] \qquad ( 1 )$$

When the surface property of the polishing pad 2 is to be evaluated, it is desirable to extract only the intensities in the spatial wavelength region that is relevant to the CMP performance (=“predetermined” spatial wavelength region). However, the obtained spatial wavelength spectrum generally contains random noises over the entire wavelength range. The calculation of the wavelength composition ratio makes it possible to exclude the influence of noises and evaluate only the reflection intensities in the predetermined spatial wavelength region.

In one embodiment, the operation controller 9 calculates dressing condition suitable for a closed-loop control based on the wavelength composition ratio determined by the data processing device 50. For example, the dressing condition is calculated such that the wavelength composition ratio changes within a preset range. In this embodiment, the operation controller 9 obtains in advance a relational expression representing a relationship between the dressing condition and the wavelength composition ratio, and determines a suitable dressing condition from the relational expression. Here, the dressing condition mainly includes a rotation speed of the polishing pad, a rotation speed of the dresser, a dressing load, a dresser oscillation (swinging) speed, etc.

For example, when the dressing load is to be controlled as the dressing condition, a relationship between the dressing load and the pad surface property is obtained in advance, i.e., how much the wavelength composition ratio increases or decreases as the dressing load increases. The calculated wavelength composition ratio is compared with a predetermined ideal wavelength composition ratio. If there is a difference between these ratios, the dressing load is set so as to come closer to the ideal wavelength composition ratio based on the above relationship.

In one embodiment, a difference between the calculated wavelength composition ratio and a predetermined desired wavelength composition ratio may be determined to be a desired amount of change in pad surface property. This desired amount of change in pad surface property may be substituted into a regression equation, which has been created in advance, to thereby determine at least one of a dressing load, a rotation speed of the dresser, a rotation speed of the polishing pad, and a dresser oscillation (swinging) speed. This regression equation is configured to represent a relationship between amount of change in pad surface property and amount of change in at least one of a dressing load, a rotation speed of the dresser, a rotation speed of the polishing pad, and a dresser oscillation (swinging) speed.

According to the above embodiment, the regression equation representing the relationship between the dressing condition (dressing load, rotation speed of the dresser, rotation speed of the polishing pad, and dresser oscillation speed, etc.) and the wavelength composition ratio is determined in advance. The amount of change in the wavelength composition ratio is substituted into the regression equation, so that an optimum dressing condition for obtaining the desired wavelength composition ratio can be uniquely determined.

The regression equation can be expressed as, for example, dR=A×dL+B, where dR is amount of change in wavelength composition ratio, dL is amount of change in dressing load, and A and B are constants. This method of determining the dressing condition can obtain an effect that the surface property of the polishing pad can be kept constant from the beginning to the end of use of the polishing pad. The surface property of the polishing pad changes depending on an amount of wear of the polishing pad and a sharpness of the dresser throughout a period from the beginning to the end of use of the polishing pad. The CMP performance also changes according to the change in the surface property of the polishing pad. Keeping the surface property of the polishing pad constant allows for keeping the CMP performance constant.

In one embodiment, the wavelength composition ratio obtained by the data processing device 50 may be used for abnormality detection. In this case, when the wavelength composition ratio deviates from a predetermined value range, the operation controller 9 determines that the pad surface property is abnormal, and emits an error notification or a notification that the dresser needs to be replaced.

Types of abnormalities in the surface property of the polishing pad include presence of abnormal points (detects) on the surface of the polishing pad, insufficient dressing of the polishing pad, the end of the service life of the dresser, the end of the service life of the polishing pad, and the like.

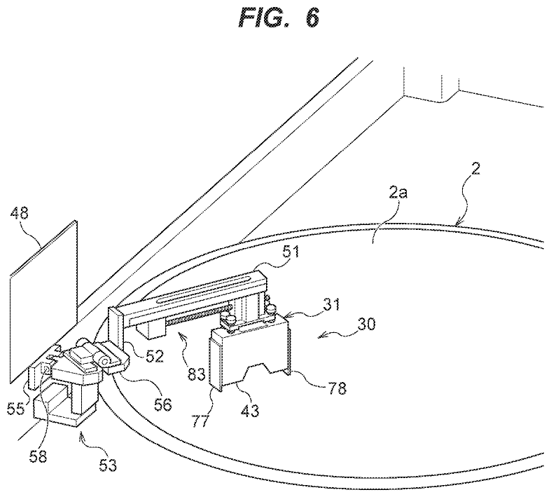

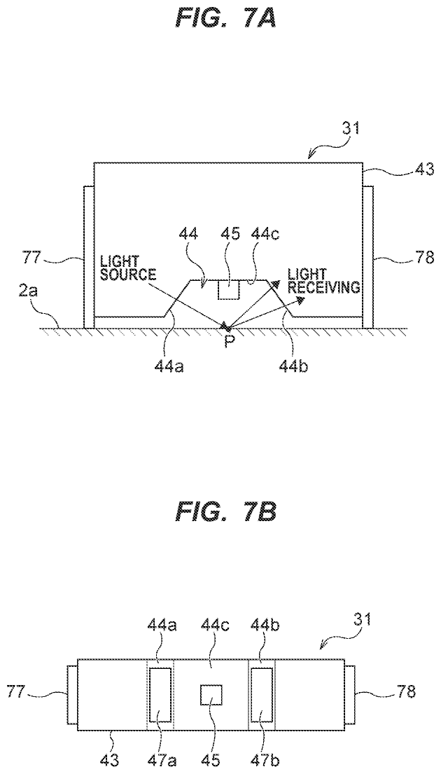

FIG. 6 is a perspective view schematically showing an embodiment in which the measuring head 31 is arranged at a measuring position. FIG. 7A is a front view of the measuring head 31, and FIG. 7B is a bottom view of the measuring head 31. As shown in FIGS. 6 and 7A, the measuring head 31 has a casing 43. The casing 43 accommodates therein a measuring structure for measuring the surface property of the polishing pad 2. The measuring structure accommodated inside the casing 43 includes, for example, the light-emitting structure 32, the light-receiving structure 35, the polarizer 38, the ND filter 39, the mirror 40, the light-reducing filter 41, etc., described with reference to FIGS. 3 and 4.

As shown in FIG. 7A, a cut 44 is formed in a lower portion of the casing 43. In this embodiment, the cut 44 has a trapezoidal shape defined by two opposing slope surfaces 44a and 44b and a coupling surface 44c coupling the slope surfaces 44a and 44b. As shown in FIG. 7B, a filter 47a having a light-transmissive property is arranged on the slope surface 44a. The laser light, emitted by the light source 33, is directed through the filter 47a to the polishing pad 2. A filter 47b having a light-transmissive property is also arranged on the other slope surface 44b, so that the light-receiving structure 35 receives the reflected light from the polishing pad 2 through the filter 47b. Examples of these filters 47a and 47b include, for example, a transparent film and transparent glass.

The measuring head 31 has positioning plates 77 and 78 fixed to sides of the casing 43. When the measuring head 31 is moved to the measuring position shown in FIGS. 6 and 7A, the positioning plates 77 and 78 come into contact with the polishing surface 2a of the polishing pad 2. The positioning plates 77, 78 make it possible to keep a constant vertical distance from the polishing surface 2a of the polishing pad 2 to the measuring structure of the measuring head 31 and keep a constant angle of the measuring head 31 with respect to the polishing surface 2a.

In one embodiment, as shown in FIGS. 7A and 7B, the surface property measuring apparatus 30 may include a nozzle 45 having a distal end protruding from the coupling surface 44c. The nozzle 45 is coupled to a pressurized-gas supply line (not shown), and is configured to blow pressurized gas (for example, pressurized nitrogen or pressurized air) supplied from the pressurized-gas supply line onto the polishing surface 2a of the polishing pad 2. The pressurized gas emitted by the nozzle 45 can remove the liquid, such as the polishing liquid or the dressing liquid on the polishing surface 2a. As a result, the surface property measuring apparatus 30 can accurately measure the surface property of the polishing pad 2.

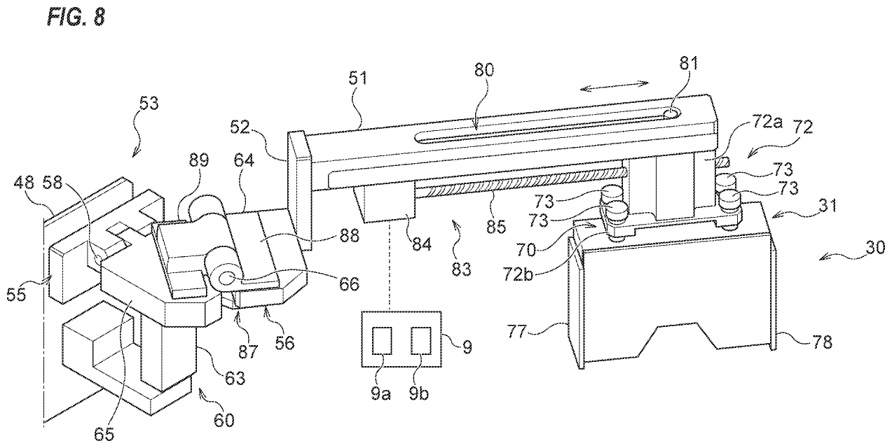

FIG. 8 is an enlarged schematic diagram showing the measuring head 31 and its surroundings shown in FIG. 6. As shown in FIGS. 6 and 8, the measuring tread 31 is supported by a support arm 51, and the support arm 51 is coupled to a moving unit 53 fixed to a part of the polishing apparatus. The moving unit 53 is configured to move the measuring head 31 from a retreated position to the measuring position and from the measuring position to the retreated position. The measuring position of the measuring head 31 is a position where the measuring head 31 is in contact with the polishing pad 2 in order to measure the surface property of the polishing pad 2. The retreated position is a position where the measuring head 31 is away from the polishing pad 2.

As shown in FIG. 8, the moving unit 53 includes a fixed block 55 fixed to a part of the polishing apparatus, a rotating block 56 coupled to the support arm 51, a rotating shaft 58 rotatably couples the rotating block 56 to the fixed block 55, and a rotating mechanism 60 configured to rotate the rotating block 56 around an axis of the rotating shaft 58. The fixed block 55 is fixed to a frame 48 of the polishing apparatus. The support arm 51 is coupled to the rotating block 56 via a support plate 52. The rotating block 56 is coupled to the fixed block 55 via the rotating shaft 58.

The rotating mechanism 60 is a piston-cylinder mechanism that includes a piston (not shown) coupled to the rotating block 56 and a cylinder 63 that accommodates the piston therein such that the piston can move back and forth. An end of the piston is coupled to the rotating block 56. A fluid supply line (not shown) is coupled to the cylinder 63, and a fluid (for example, pressurized nitrogen or pressurized air) is supplied into the cylinder 63 through the fluid supply line. The operation controller 9 controls the supply of fluid to the cylinder 63 so that the piston moves up and down. For example, an on-off valve (not shown) is arranged in the fluid supply line, and the operation controller 9 controls the operation of this on-off valve to cause the piston to move up and down. More specifically, when the piston is to be elevated, the operation controller 9 opens the on-off valve to supply the fluid to the cylinder 63. When the piston is to be lowered, the operation controller 9 closes the on-off valve to stop the supply of fluid to the cylinder 63.

When the piston of the rotating mechanism 60 is elevated, the rotating block 56 and the support arm 51 are rotated in a direction as to move the measuring head 31 upward. When the piston is lowered, the rotating block 56 and the support arm 51 are rotated in a direction as to move the measuring head 31 downward. When the surface property of the polishing pad 2 is to be measured, the operation controller 9 causes the piston of the rotating mechanism 60 to move downward. As a result, the positioning plates 77 and 78 of the measuring head 31 come into contact with the polishing pad 2, so that the measuring head 31 is located at the measuring position. After the measuring of the surface property of the polishing pad 2 is terminated, the operation controller 9 causes the piston of the rotating mechanism 60 to move upward. As a result, the measuring head 31 is separated from the polishing pad 2, and the measuring head 31 moves to the retreated position.

As shown in FIG. 8, the rotating block 56 includes a first plate 64 coupled to the support plate 52 and a second plate 65 coupled to the fixed block 55 via the rotating shaft 58. The first plate 64 is rotatably coupled to the second plate 65 by a hinge mechanism 87. The hinge mechanism 87 includes a first joint 88 fixed to an upper surface of the first plate 64, a second joint 89 fixed to an upper surface of the second plate 65, and a rotating pin 66 rotatably couples the first joint 88 to the second joint 89. When the hinge mechanism 87 is operated, the support arm 51 can be tilted further upward. As a result, the measuring head 31 can be located farther away from the polishing pad 2, so that maintenance or replacement of the polishing pad 2 can be easily conducted.

The polishing apparatus further includes a posture adjusting mechanism 70 configured to automatically adjust a posture of the measuring head 31. The posture adjusting mechanism 70 includes a support base 72 coupled to the support arm 51 and a plurality of adjustment pins 73 fixed to the upper surface of the measuring head 31 and extending through through-holes formed in the support base 72. In this embodiment, four adjustment pins 73 are fixed to the upper surface of the measuring head 31. The support base 72 has a column 72a coupled to the support arm 51 and a flange portion 72b fixed to a lower portion of the column 72a. Four through-holes are formed in four corners of the flange portion 72b. Each adjustment pin 73 extends through a respective through-hole formed in the flange portion 72b.

An upper portion of each adjustment pin 73 has a diameter larger than a diameter of each through-hole, and a diameter of a portion of each adjustment pin 73 penetrating the flange portion 72b is smaller than the diameter of the through-hole. Therefore, the measuring head 31 is movable toward the support base 72 and away from the support base 72. When the positioning plates 77 and 78 of the measuring head 31 are brought into contact with the polishing surface 2a of the polishing pad 2, the measuring head 31 is supported by the polishing surface 2a of the polishing pad 2 by own weight of the measuring head 31. Therefore, the posture of the measuring head 31 is adjusted such that the lower surface of the measuring head 31 is parallel to the surface (polishing surface 2a) of the polishing pad 2.

The polishing apparatus further includes a measuring-head moving mechanism 83 as an actuator for moving the measuring head 31 in a longitudinal direction of the support arm 51. The support arm 51 is arranged to extend in the radial direction of the polishing pad 2 when the measuring head 31 is in the measuring position. Therefore, the measuring-head moving mechanism 83 moves the measuring head 31 in the radial direction of the polishing pad 2. The measuring-head moving mechanism 83 includes a ball screw mechanism 85 coupled to the support base 72 and a servomotor 84 coupled to the ball screw mechanism 85. The servomotor 84 is fixed to a lower surface of the support arm 51.

The support arm 51 has an elongated hole 80 extending along the longitudinal direction of the support arm 51. A stepped portion (not shown) is formed inside the elongated hole 80. A support shaft 81 is fixed to an upper end of the column 72a. The support shaft 81 contacts the stepped portion of the elongated hole 80 and is supported by the stepped portion of the elongated hole 80 so as to be movable in a longitudinal direction of the elongated hole 80. With such configurations, the measuring head 31 and the posture adjusting mechanism 70 are movable in the longitudinal direction of the support arm 51. Specifically, the elongated hole 80 functions as a guide hole for moving the posture adjusting mechanism 70 and the measuring head 31 along the support arm 50.

The measuring-head moving mechanism 83 is electrically coupled to the operation controller 9. The operation of the measuring-head moving mechanism 83 is controlled by the operation controller 9. When the operation controller 9 instructs the servomotor 84 to drive the ball screw mechanism 85, the posture adjusting mechanism 70 and the measuring head 31 are moved in the longitudinal direction of the support arm 51 (i.e., in the radial direction of the polishing pad 2). In one embodiment, the measuring-head moving mechanism 83 may be a combination of an air cylinder and a pressure regulator.

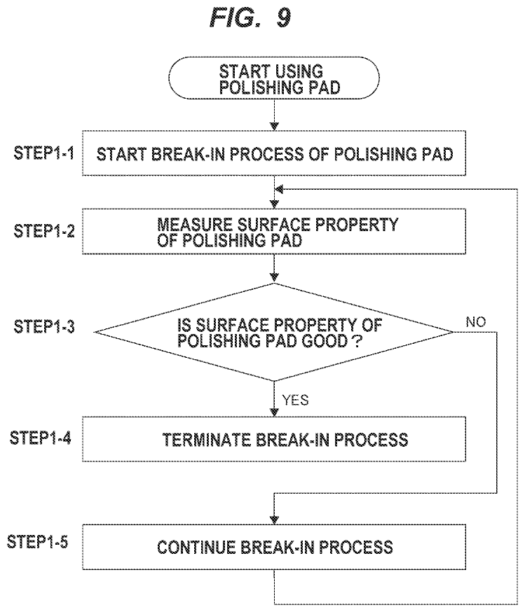

Next, an embodiment of the surface property judging method for the polishing pad 2 using the surface property measuring apparatus 30 and the surface property measuring method described above will be described with reference to FIG. 9. FIG. 9 is a flow chart showing an example in which the surface property judging method for the polishing pad 2 is incorporated into a break-in process of the polishing pad 2.

First, an unused polishing pad 2 is placed on the polishing table 1, and the break-in process of the polishing pad 2 is started (step 1-1). The break-in process is a process of making a surface (i.e., a polishing surface) of an unused polishing pad suitable for polishing. The break-in process includes at least a process (seasoning process) of performing only dressing of the polishing pad 2. In one embodiment, the break-in process may further include a composite process. The composite process is a process of dressing the polishing pad 2 after polishing of one dummy wafer on which an oxide film (SiO₂) or a metal film is formed. The composite process may be repeated multiple times with different dummy wafers to be polished. In one embodiment, a predetermined number of composite processes may be performed after the seasoning process.

During the break-in process, the surface property of the polishing pad 2 is measured (step 1-2). In one embodiment, the surface property of polishing pad 2 is measured after dressing (seasoning process) of polishing pad 2 is performed for a predetermined period of time or after a predetermined number of composite processes are performed.

In step 1-2, the surface property of the polishing pad 2 is measured. Specifically, a plurality of intensity distributions of the reflected lights from the polishing pad 2 are obtained (measured) at a plurality of different points (measurement points) on the surface of the polishing pad 2. Wavelength composition ratios indirectly indicating the surface property of the polishing pad 2 are calculated from the plurality of intensity distributions obtained at the plurality of different points. The process of obtaining each intensity distribution of the reflected light from the polishing pad 2 is as follows. The light-emitting structure 32 irradiates the surface of the polishing pad 2 with the laser light, and the light-receiving structure 35 receives the reflected light from the polishing pad 2. The light-receiving structure 35 acquires the intensity distribution of the reflected light from the polishing pad 2 by receiving the reflected light from the polishing pad 2.

The process of calculating the wavelength composition ratios that indirectly indicate the surface property of the polishing pad 2 from the plurality of intensity distributions obtained at the plurality of different points is as follows. In this embodiment, a wavelength composition ratio is calculated from each of the plurality of intensity distributions, so that the plurality of wavelength composition ratios are calculated. Specifically, the intensity distribution of reflected light acquired at each point is transmitted to the data processing device 50. The data processing device 50 then calculates a wavelength composition ratio that indirectly indicates the surface property of the polishing pad 2 from the intensity distribution of the reflected light. More specifically, the data processing device 50 converts the intensity distribution of the reflected light into a spatial wavelength spectrum of the surface of the polishing pad 2 by performing Fourier transform on the intensity distribution of the reflected light, and calculates the wavelength composition ratio from the spatial wavelength spectrum. Specifically, in the present embodiment, the surface property measurement process for the polishing pad 2 from the irradiation of the polishing pad 2 with the laser light to the calculation of the wavelength composition ratio described above is performed a plurality of times while changing the irradiation position of the laser light.

In one embodiment, the data processing device 50 may calculate an average of the plurality of intensity distributions and may calculate, from the average of the plurality of intensity distributions, a wavelength composition ratio that indirectly indicates the surface property of the polishing pad 2. Specifically, the data processing device 50 determines the average of the plurality of intensity distributions by calculating an average of intensities at each one of corresponding pixels of the plurality of intensity distributions. After the average of the intensity distributions is calculated, the wavelength composition ratio can be efficiently calculated.

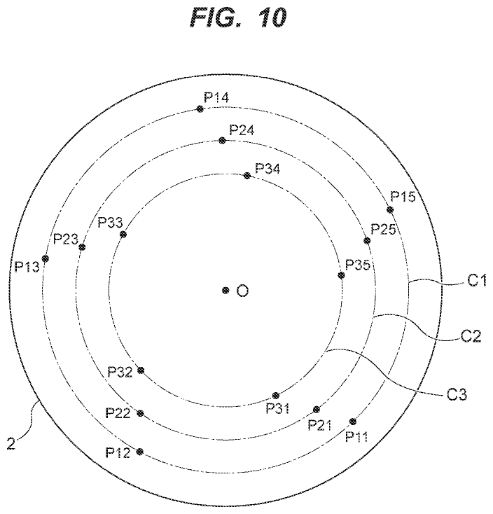

The intensity distributions of the reflected lights from the polishing pad 2 are acquired (measured) at a plurality of points on at least one circle centered on the center O of the polishing pad 2. In one embodiment, the intensity distributions are measured at a plurality of points on a plurality of concentric circles centered on the center O of the polishing pad 2. FIG. 10 is a diagram showing an example of a plurality of measurement points on the surface of polishing pad 2. In the example shown in FIG. 10, the intensity distributions are measured at a plurality of measurement points P11 to P15, P21 to P25, P31 to P35 on a plurality of concentric circles C1, C2, C3 centered on the center O of the polishing pad 2. The number of measurement points for the intensity distributions is not limited to this example.

In one embodiment, measuring of the intensity distribution of reflected light from the polishing pad 2 at multiple points on the surface of the polishing pad 2 is performed as follows. First, the measuring head 31 is moved to a predetermined position, and the intensity distribution is measured. Next, the polishing table 1 is rotated together with the polishing pad 2 by a predetermined angle, and the intensity distribution of the reflected light from the polishing pad 2 is measured again. By repeating the rotation of the polishing table 1 and the measuring of the intensity distribution described above while the position of the measuring head 31 is fixed, the measuring of the intensity distribution is performed multiple times on the same circle having a center on the center O. After the intensity distribution of the reflected light from the polishing pad 2 is measured a predetermined number of times, the measuring-head moving mechanism 83 moves the measuring head 31 in the radial direction of the polishing pad 2. Similarly, the intensity distribution of the reflected light from the polishing pad 2 is measured at a plurality of points on the same circle which is the other one of the concentric circles around the center O. The rotation of the polishing table 1, the measuring of the intensity distribution, and the movement of the measuring head 31 in the radial direction of the polishing pad 2 are repeated, so that the plurality of intensity distributions of the reflected lights from the polishing pad 2 can be measured at multiple points on the multiple concentric circles around the center O of the polishing pad 2.

In step 1-3, whether the surface property of the polishing pad 2 is good or not is judged based on the wavelength composition ratio calculated in the step 1-2. The data processing device 50 transmits the wavelength composition ratio calculated in the step 1-2 to the operation controller 9. The operation controller 9 then judges whether the surface property of the polishing pad 2 is good or not based on the calculated wavelength composition ratio. When the operation controller 9 judges that the surface property of the polishing pad 2 is good, the operation controller 9 instructs each component of the polishing apparatus to end the break-in process.

In one embodiment in which the plurality of wavelength composition ratios are calculated from the plurality of intensity distributions, respectively, the operation controller 9 calculates an average of the plurality of calculated wavelength composition ratios, and compares the average with a predetermined threshold value. When the average is smaller than the threshold value, the operation controller 9 determines that the surface property of the polishing pad 2 is good (the surface of the polishing pad 2 has become suitable for polishing) and terminates the break-in process (step 1-4). When the average is larger than the threshold value, the operation controller 9 determines that the surface property of the polishing pad 2 is not good (the surface of the polishing pad 2 is not suitable for polishing) and continues the break-in process (step 1-5). The seasoning process is performed for a predetermined time or the composite process is performed a predetermined number of times, and then the step 1-2 is executed again.

In one embodiment, the wavelength composition ratio calculated from the average of the intensity distributions of the reflected lights may be compared with a predetermined threshold value. In this embodiment, when the wavelength composition ratio is smaller than the threshold value, the operation controller 9 determines that the surface property of the polishing pad 2 is good, and terminates the break-in process. When the wavelength composition ratio is larger than the threshold value, the operation controller 9 determines that the surface property of the polishing pad 2 is not good, and continues the break-in process. The seasoning process is performed for a predetermined time or the composite process is performed a predetermined number of times, and then the step 1-2 is executed again.

In one embodiment, when the average (or the wavelength composition ratio calculated from the average of the intensity distributions of the reflected light) is larger than the threshold value, the operation controller 9 may determine that the surface property of the polishing pad 2 is good and may terminate the break-in process. Depending on the spatial wavelength regions selected for calculating the wavelength composition ratio, the surface property of the polishing pad 2 may be good when the above average (or the wavelength composition ratio calculated from the average of the intensity distributions of the reflected light) is larger than the threshold value.

In one embodiment, the operation controller 9 may determine whether or not the calculated wavelength composition ratios are within a predetermined reference range. When all of the calculated wavelength composition ratios are within the predetermined range, the operation controller 9 may determine that the surface property of the polishing pad 2 is good and may terminate the break-in process. If all of the wavelength composition ratios are not within the predetermined reference range, the operation controller 9 may determine that the surface property of the polishing pad 2 is not good, and continues the break-in process. The seasoning process is performed for a predetermined time or the composite process is performed a predetermined number of times, and then the step 1-2 is executed again.

Furthermore, in one embodiment, the operation controller 9 may calculate an average of the calculated wavelength composition ratios, compare the average with a predetermined threshold value, and determine whether the calculated wavelength composition ratios are within a predetermined reference range. When the average is smaller (or larger) than the threshold value, and all of the calculated wavelength composition ratios are within the predetermined reference range, the operation controller 9 may determine that the surface property of the polishing pad 2 is good and may terminate the break-in process. The threshold value and the reference range described above can be determined from measurement data of the surface property of the polishing pad 2 obtained in advance after dressing or after the break-in process.

When the dressing and the break-in process of the polishing pad 2 are appropriately performed, the raised portions of the uneven structure of the polishing surface 2a stand, and an in-plane uniformity of the uneven structure is improved. As a result, the wavelength composition ratios at a plurality of measurement points on the surface of the polishing pad 2 and an in-plane variation are reduced. In other words, each wavelength composition ratio indirectly indicates the surface property of the polishing pad 2. Therefore, the judgement of the surface property of the polishing pad 2 (for example, detection of insufficient dressing or determination of dressing end) can be performed based on the wavelength composition ratio.

In addition, by acquiring the intensity distributions of the reflected lights from the polishing pad 2 at a plurality of points on the surface of the polishing pad 2, an in-plane variation in the surface property of the polishing pad can be evaluated. In this way, according to the embodiments in which the intensity distributions of the reflected lights from the polishing pad 2 are obtained at a plurality of points instead of at one point, the surface property of the polishing pad 2 (the surface property of the entire polishing pad 2) can be accurately judged. As a result, excessive dressing and excessive break-in can be prevented, and the service life of the dresser is increased. Furthermore, this contributes to process shortening and reduction of consumables, such as slurry. Further, according to the surface property judging method described above, a break-in time can be shortened for a polishing pad whose raised portions stand quickly, while a sufficient break-in process can be performed on a polishing pad whose raised portions stand slowly. In other words, the break-in time can be adjusted according to individual difference of polishing pads.

In one embodiment, the above-described steps 1-2 to 1-5 may be performed each time a used polishing pad is replaced with a new polishing pad (unused polishing pad), and termination of the break-in process may be individually determined. Furthermore, in one embodiment, the steps 1-2 to 1-5 may be performed once for a new polishing pad to determine an appropriate break-in condition. When a used polishing pad is replaced with a new polishing pad, the break-in process may be performed under the determined break-in condition. In one embodiment, a plurality of break-in termination conditions may be determined by executing the steps 1-2 to 1-5 in break-in processes of a plurality of brand-new polishing pads, and an upper limit of a break-in termination condition may be determined based on the plurality of break-in termination conditions.

FIG. 11 is a graph showing an example of the wavelength composition ratio under each processing condition of the polishing pad 2 during a break-in process. FIG. 11 shows results which were obtained as follows. The polishing pad 2 was processed under each processing condition, and the intensity distributions of reflected lights from the polishing pad 2 were then measured at a plurality of points on the polishing pad 2.

The wavelength composition ratios were calculated fron the intensity distributions, respectively. The measured values in FIG. 11 show measured values (wavelength composition ratios) obtained at respective measuring positions on the polishing pad. Examples of the processing conditions shown in FIG. 11 include seasoning time and the number of composite processes. In FIG. 11, in the conditions 2 to 6, the larger the condition number, the longer the seasoning time. In the conditions 7 to 10, the larger the condition number, the greater the number of composite processes. In the conditions 2 to 6, only the seasoning process was performed. In conditions 7 to 10, after the seasoning process was performed for a predetermined period of time, the composite process was performed a predetermined number of times. Dressing times in the composite processes of the conditions 7 to 10 were the same, and the seasoning times of the conditions 7 to 10 were the same. The measurement results of the condition 1 show measurement results of an unused polishing pad before the break-in process.

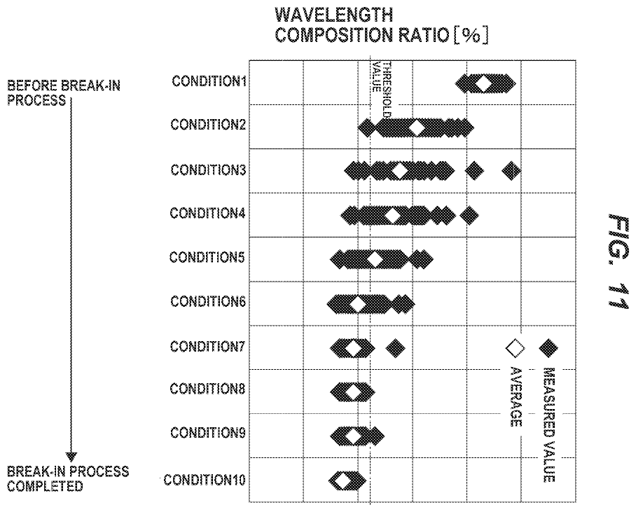

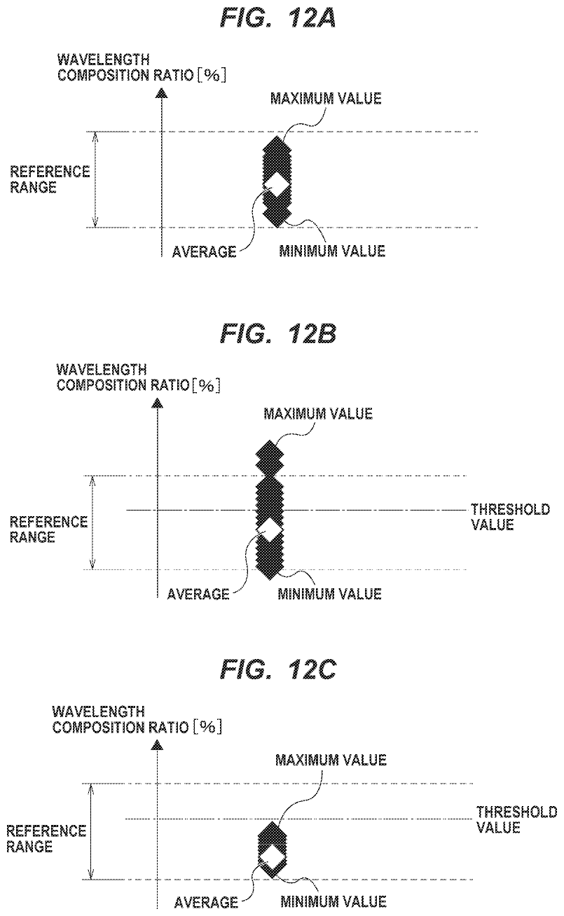

FIG. 12A is a diagram comparing the wavelength composition ratios under the condition 1 in FIG. 11 with a predetermined reference range and a predetermined threshold value, FIG. 12B is a diagram comparing the wavelength composition ratios under the condition 6 in FIG. 11 with the predetermined reference range and the predetermined threshold value, and FIG. 12C is a diagram comparing the wavelength composition ratios under the condition 10 in FIG. 11 with the predetermined reference range and the predetermined threshold value.

In FIG. 12A, the threshold value is not shown because the threshold value is significantly below the measured values (calculated values) of the wavelength composition ratios.

As shown in FIG. 12A, under the condition 1, all the measured values of the wavelength composition ratios are within the reference range, but the average of the wavelength composition ratios is larger than the threshold value. As shown in FIG. 12B, under the condition 6, all the measured values of the wavelength composition ratios are not within the reference range, but the average of the wavelength composition ratios is smaller than the threshold value. As shown in FIG. 12C, under the condition 10, all the measured values of the wavelength composition ratios are within the reference range, and the average of the wavelength composition ratios is smaller than the threshold value.

Therefore, by comparing the plurality of calculated wavelength composition ratios with the predetermined threshold value and checking whether or not the plurality of calculated wavelength composition ratios are within the predetermined reference range, a more accurate break-in end determination can be achieved.

As shown in FIG. 11, for example, in the measurement after the condition 3, it can be seen that some measured values are below the threshold value (however, measured values at other measurement points are significantly larger than the threshold value, which means that the break-in process is insufficient). In the above-described embodiment, since the wavelength composition ratios indirectly indicating the surface property of the polishing pad 2 are calculated from the plurality of intensity distributions obtained at a plurality of different points, it can be determined whether or not the entire polishing pad is in a state suitable for polishing.

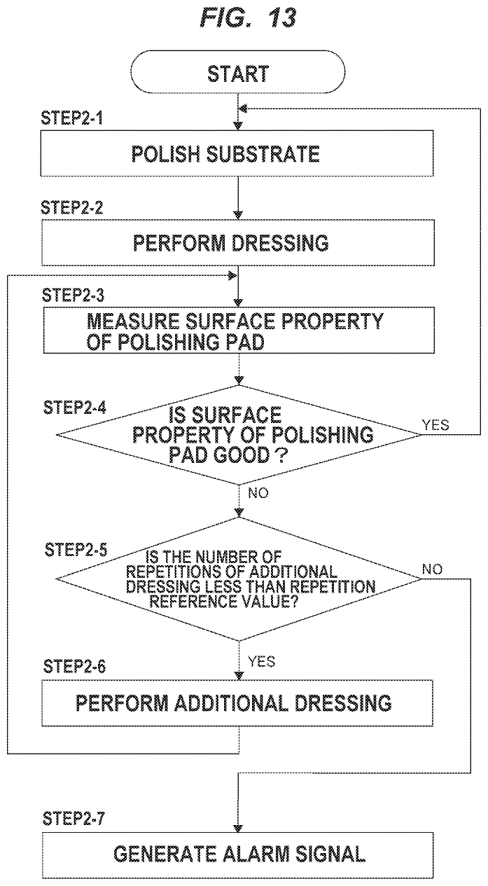

Next, another embodiment of the surface property judging method for the polishing pad 2 using the surface property measuring apparatus 30 and the surface property measuring method described above will be described with reference to FIG. 13. FIG. 13 is a flow chart showing an example in which the surface property judging method for the polishing pad 2 is incorporated into the polishing process of the substrate W. The surface property judging method of this embodiment, which will not specifically be described, is the same as the steps 1-2 and 1-3, and repetitive descriptions thereof will be omitted.

In step 2-1, the substrate W is polished. In step 2-2, dressing of the polishing pad 2 is performed. In one embodiment, the dressing of the polishing pad 2 may be performed at the same time as the substrate W is polished. In one embodiment, the dressing of the polishing pad 2 may be performed each time a predetermined number of substrates are polished. After dressing of the polishing pad 2 for a predetermined period of time, the surface property of the polishing pad 2 is measured in the same way as in the step 1-2 (step 2-3). In one embodiment, the step 2-3 may be performed at any timing (e.g., after each dressing, each time one lot of substrates are polished, or after dressing is performed after polishing of a predetermined number of substrates). In step 2-4, whether the surface property of the polishing pad 2 is good or not is judged in the same way as in the step 1-3. In one embodiment, the surface property judging process (steps 2-3 to 2-5) may be performed simultaneously with dressing of the polishing pad 2.

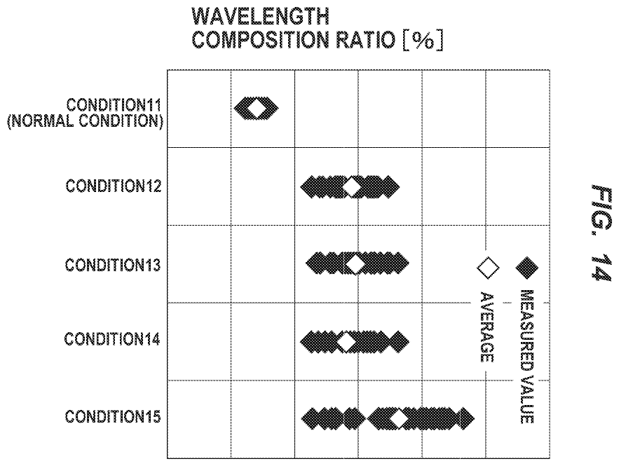

FIG. 14 shows the result of measuring of the surface property of the polishing pad 2 after dressing of the polishing pad 2 is performed under predetermined dressing condition while the substrate W is polished, and calculating the wavelength composition ratio. One example of the dressing condition shown in FIG. 14 is the number of scans of the dresser arm 21. In FIG. 14, the number of scans of the dresser arm 21 decreases as the condition number increases. Condition 11 in FIG. 14 is a dressing condition when the polishing pad 2 is appropriately dressed (i.e., when the surface property of the polishing pad 2 is good). Conditions 12 to 15 in FIG. 14 show measurement results of the surface property of the polishing pad 2 after the polishing pad 2 was dressed only during polishing of the substrate W. The condition 11 shows measurement results of the surface property of the polishing pad 2 after dressing of the polishing pad 2 was performed under predetermined condition during polishing of the substrate W and then dressing of the polishing pad 2 was performed again after polishing of the substrate W.

When the operation controller 9 judges that the surface property of the polishing pad 2 is good (i.e., the dressing is properly performed), polishing of a new substrate is started. When the operation controller 9 judges that the surface property of the polishing pad 2 is not good (insufficient dressing), the operation controller 9 compares the number of repetitions of additional dressing in step 2-6, which will be described later, with a predetermined repetition reference value (step 2-5). If the number of repetitions is larger than the predetermined repetition reference value, the operation controller 9 generates an alarm signal to prompt an operator to consider replacing consumables of the polishing apparatus (step 2-7). Example of the consumables of the polishing apparatus include the polishing pad 2, the dressing member 22a, and slurry.

If the number of repetitions is less than the predetermined repetition reference value, additional dressing of the polishing pad 2 is performed under predetermined dressing condition (step 2-6). After the additional dressing is performed, the step 2-3 is performed again. In one embodiment, the dressing condition (e.g., dressing time) in the step 2-6 may differ from the dressing condition in the step 2-2. Also in the present embodiment, the intensity distributions of reflected lights from the polishing pad 2 are obtained at a plurality of points. Therefore, the surface property of the polishing pad 2 (the surface property of the entire polishing pad 2) can be accurately judged. According to the present embodiment, the lack of dressing is determined, and if necessary, the additional dressing is performed, and polishing is continued. This snakes it possible to accurately determine whether a consumable (for example, the dressing member) is to be replaced based on the surface property of the polishing pad.

In one embodiment, the steps 2-2 to 2-6 may be a series of dressing processes performed after (or during) polishings of the substrate W, and the end of the dressing processes may be determined in the step 2-4. Specifically, when the operation controller 9 determines in the step 2-4 that the surface property of the polishing pad 2 is good, the operation controller 9 instructs each component of the polishing apparatus to terminate the dressing processes. According to this embodiment, the surface property of the polishing pad 2 can be determined with high accuracy, and excessive dressing can be prevented.

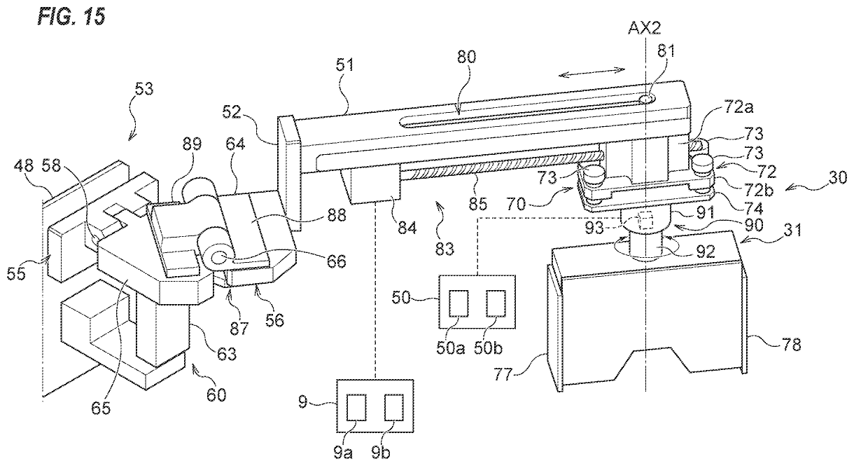

FIG. 15 is a schematic diagram showing another embodiment of the surface property measuring apparatus 30. Configurations and operations of the present embodiment, which will not be specifically described, are the same as those of the above-discussed embodiments, and repetitive descriptions thereof will be omitted. The light-emitting structure 32 of the present embodiment is configured to be able to irradiate the polishing pad 2 with light from a plurality of directions as viewed from the polishing-surface-2a side of the polishing pad 2. The light-receiving structure 35 is configured to be able to receive reflected lights in a plurality of directions traveling from the polishing surface of the polishing pad 2. In this specification, irradiating direction of the laser light means irradiating direction of the laser light as viewed from the surface side (polishing-surface-2a side) of the polishing pad 2.

The surface property measuring apparatus 30 of this embodiment further includes an irradiating-direction changing mechanism 90 configured to change the irradiating direction of the laser light emitted by the light-emitting structure 32. The irradiating-direction changing mechanism 90 is coupled to the measuring head 31. The irradiating-direction changing mechanism 90 rotatably supports the measuring head 31 and is configured to change the irradiating direction of the laser light emitted by the light-emitting structure 32 by rotating the measuring head 31.

The irradiating-direction changing mechanism 90 includes a rotating motor 91 configured to rotate the measuring head 31, and a shaft 92 coupled to the rotating motor 91. The measuring head 31 is coupled to the rotating motor 91 via the shaft 92. The rotating motor 91 rotates the measuring head 31 about an axis AX2 of the shaft 92 in directions indicated by arrows. The rotating motor 91 includes an angle measuring device 93 configured to measure a rotation angle of the measuring head 31. The rotating motor 91 is configured to be able to control its rotation angle. An example of the rotating motor 91 is a servomotor. An example of the angle measuring device 93 is a rotary encoder.

The irradiating-direction changing mechanism 90 is electrically coupled to the data processing device 50, and operation of the irradiating-direction changing mechanism 90 is controlled by the data processing device 50. The irradiating-direction changing mechanism 90 is fixed to a lower surface of the base plate 74 and coupled to the posture adjusting mechanism 70 via the base plate 74. In this embodiment, lower ends of the adjustment pins 73 are fixed to the upper surface of the base plate 74. In one embodiment, the shaft 92 may be rotatably supported by a bearing (not shown) instead of the rotating motor 91. In this case, the measuring head 31 may be manually rotated, and the irradiating-direction changing mechanism 90 may not be electrically coupled to the data processing device 50.

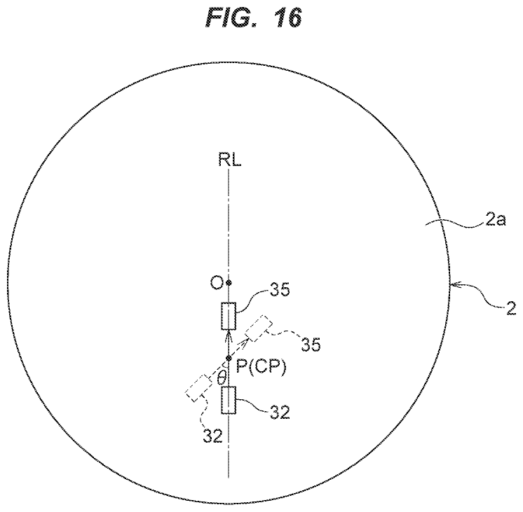

The light-emitting structure 32 and the light-receiving structure 35 are rotated about the axis AX2 of the shaft 93. In this embodiment, the axis AX2 coincides with an axis CP (see FIG. 2) which is a straight line passing through the irradiation position P of the laser light and perpendicular to the polishing surface 2a. Therefore, as shown in FIG. 16, the light-emitting structure 32 and the light-receiving structure 35 are configured to be rotatable about the axis CP. When the rotating motor 91 is in motion, the measuring head 31, i.e., the light-emitting structure 32 and the light-receiving structure 35, is rotated about the axis CP. As a result, the irradiating direction of the laser light emitted by the light-emitting structure 32 is changed.

In this embodiment, the irradiating direction of the laser light can also be said to be an angle around the axis CP. In other words, the irradiating angle θ of the laser light is an angle between a reference straight line RL and the laser light emitted by the light source 33 of the light-emitting structure 32 as viewed from a direction perpendicular to the surface (polishing surface 2a) of the polishing pad 2. The reference straight line RL is a straight line passing through the irradiation position P and the center O of the polishing pad 2. In this embodiment, the irradiating direction of the laser light can be changed without moving the irradiation position of the laser light.

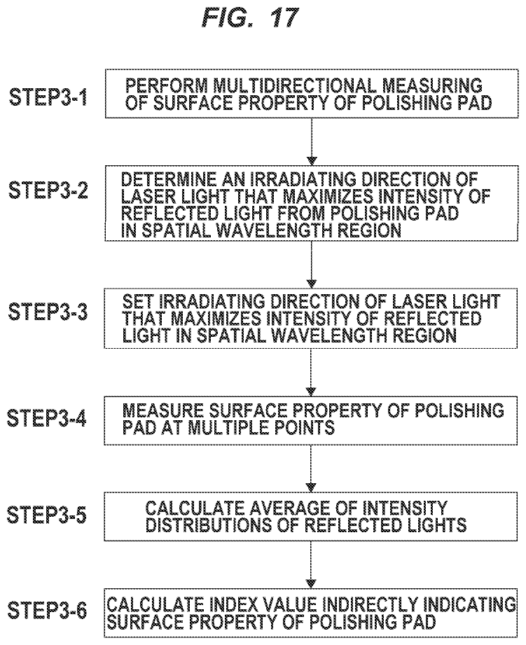

Next, one embodiment of the surface property measuring method for the polishing pad 2 using the surface property measuring apparatus 30 of this embodiment will be described with reference to flow chart of FIG. 17. In step 3-1, multidirectional measuring of the surface property of the polishing pad 2 (intensity distribution of reflected light from the polishing pad 2) is performed. The multidirectional measuring of the surface property of the polishing pad 2 is performed by irradiating the polishing pad 2 with laser lights from a plurality of different irradiating directions, receiving reflected lights from the polishing pad 2 by the light-receiving structure 35 corresponding to the laser lights irradiating the polishing pad 2, and obtaining intensity distributions of the reflected lights. Specifically, the light-emitting structure 32 directs the laser light to the polishing pad 2 while the irradiating direction of the laser light is being changed, and the light-receiving structure 35 receives each reflected light from the polishing pad 2 in each irradiating direction, so that the intensity distributions are obtained.

More specifically, the light-emitting structure 32 irradiates the polishing pad 2 with the laser light in a predetermined irradiating direction, and the light-receiving structure 35 receives the reflected light from the polishing pad 2. The light-receiving structure 35 obtains the intensity distribution of the reflected light from the polishing pad 2 by receiving the reflected light from the polishing pad 2. The irradiating direction of the laser light is then changed by a predetermined angle by the irradiating-direction changing mechanism 90. The light-emitting structure 32 irradiates the polishing pad 2 with the laser light in the changed irradiating direction, and the light-receiving structure 35 receives the reflected light from the polishing pad 2 and obtains the intensity distribution of the reflected light. The irradiating direction of the laser light is further changed by a predetermined angle, and the surface property of the polishing pad 2 is measured from the changed direction. In this manner, the changing of the irradiating direction of the laser light and the measuring of the surface property of the polishing pad 2 are repeated a predetermined number of times (for example, until the light source 33 makes one rotation around the axis CP).

The measuring position in the multidirectional measuring of the surface property of the polishing pad 2 in this embodiment is a position on the polishing pad 2 at which the central portion of the substrate W contacts the polishing pad 2 during polishing of the substrate W. Insufficient dressing may be likely to occur in a portion of the polishing pad 2 where the central portion of the substrate W contacts the polishing pad 2, and as a result, the intensity of the reflected light may be relatively high. In one embodiment, the surface property of the polishing pad 2 may be measured multiple times in each irradiating direction, an average of the intensity distributions of multiple reflected lights may be calculated, and the average of the intensity distributions may be used in step 3-2 which will be described later. Since the average of the intensity distributions of the reflected lights is calculated, the measurement variation can be reduced and the accuracy of the measurement result can be improved.

In steps 3-2 to 3-6, the data processing device 50 obtains an index value that indirectly indicates the surface property of the polishing pad 2 using the plurality of intensity distributions obtained in the multidirectional measuring in the step 3-1. The data processing device 50 of the present embodiment is configured to utilize the intensity distributions of the plurality of reflected lights from the polishing pad 2 corresponding to the plurality of lights directed to the polishing pad 2 in multiple different directions to determine the index value that indirectly indicates the surface property of the polishing pad 2.

The specific details of the steps 3-2 to 3-6 are as follows. In the step 3-2, the data processing device 50 compares the intensity distributions of the reflected lights from the polishing pad 2 with each other to determine an irradiating direction of the laser light that maximizes the intensity of the reflected light from the polishing pad 2 in a spatial wavelength region. More specifically, the data processing device 50 calculates an average of intensities in a specific spatial wavelength region of each intensity distribution (i.e., an average of intensities in pixels within a predetermined range that receive reflected light in a specific spatial wavelength region of the light-receiving element 36) to obtain averages of the intensity distributions, compares these averages with each other, and determines an irradiating direction corresponding to a largest one of the averages.

In one embodiment, the data processing device 50 may compare intensities of the reflected lights at a predetermined pixel (pixel position) in the respective irradiating directions with each other and may determine an irradiating direction corresponding to a highest one of the intensities of the reflected lights at the predetermined pixel. Furthermore, in one embodiment, the data processing device 50 may select a pixel that is most susceptible to a change in irradiating direction (i.e., a pixel that exhibits the largest change in intensity depending on the irradiating direction) as a pixel for use in comparing -the intensity of reflected light. Alternatively, a pixel haying a highest intensity of reflected light among the plurality of intensity distributions of reflected lights may be used as a pixel for comparing the intensity of reflected light.

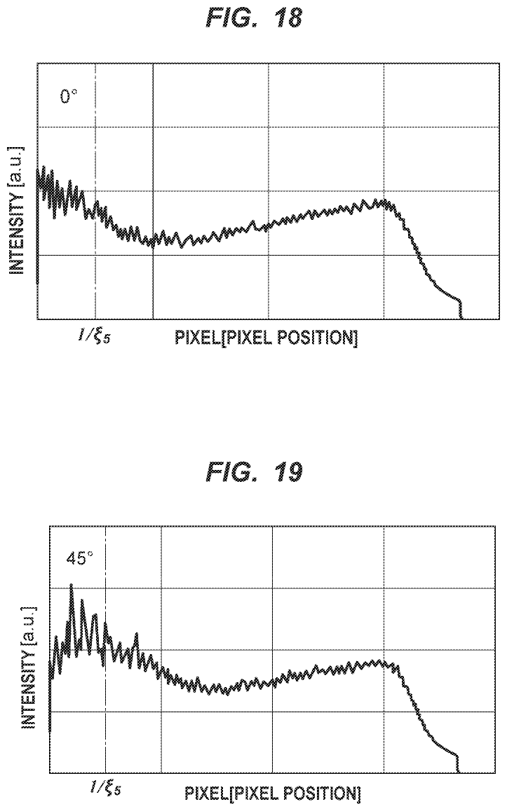

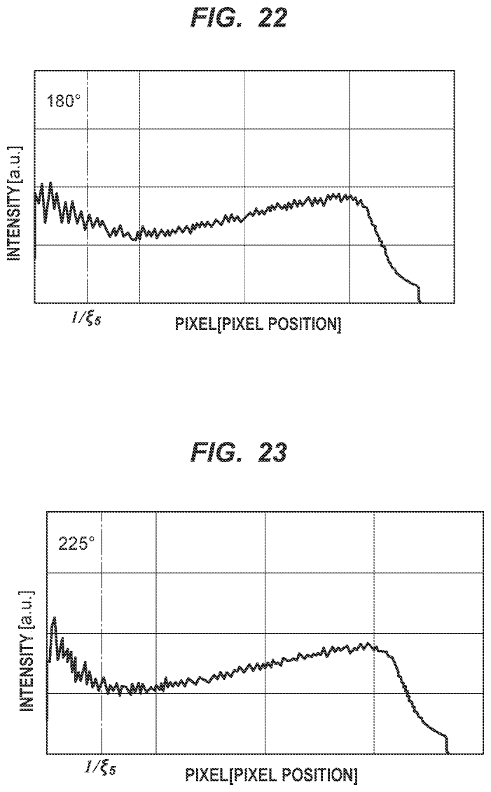

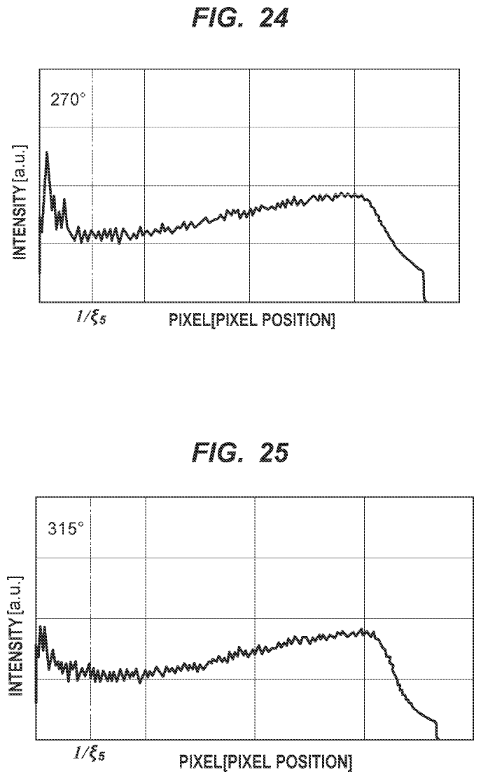

FIGS. 18 to 25 are graphs each showing the intensity distribution of the reflected light from the polishing pad 2 in each irradiating direction. Horizontal axes of the graphs of FIGS. 18 to 25 represent pixel (pixel position), and vertical axes represent the intensity of the reflected light from the polishing pad 2 at each pixel. FIGS. 18 to 25 show the graphs of the intensity distributions of the reflected light from the polishing pad 2 when the irradiating angles θ are 0°, 45°, 90°, 135°, 180°, 225°, 270° and 315°, respectively.

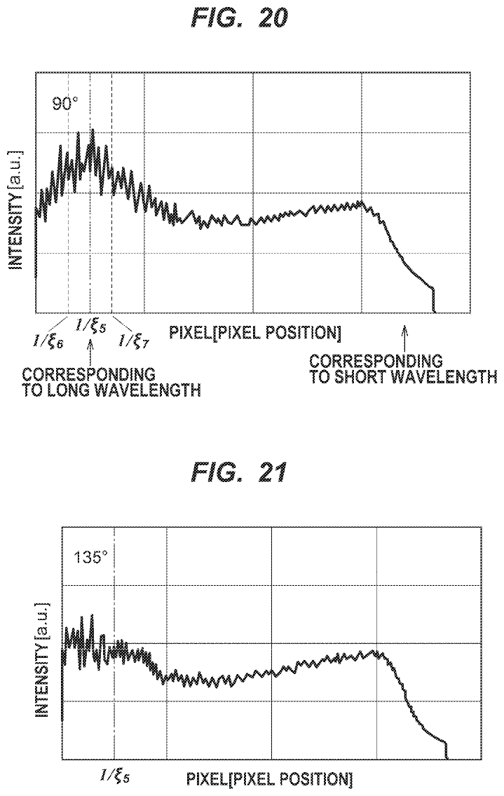

In the examples shown in FIGS. 18 to 25, changes in intensity at a pixel receiving the light of a spatial frequency 1/ξ₅ (hereinafter simply referred to as pixel 1/ξ₅) and its neighboring pixels are relatively large. In addition, a maximum value of the intensity at the pixel 1/ξ₅ (i.e., the intensity of the reflected light at the pixel 1/ξ₅ when the irradiating angle θ is 90°) is also relatively large. Therefore, in the examples shown in FIGS. 18 to 25, the data processing device 50 may compare the intensity distributions of the reflected lights with each other and may determine an irradiating direction that maximizes the intensity of the reflected light at the pixel 1/ξ₅. Alternatively, the data processing device 50 may compare the intensity distributions of the reflected lights with each other and may determine an irradiating direction corresponding to a largest average of intensities at pixels (i.e., a spatial wavelength region from a spatial frequency ξ₆ to a spatial frequency ξ₇) in a range from a pixel 1/ξ₆ to a pixel 1/ξ₇ which are neighboring pixels of the pixel 1/ξ₅ as shown in FIG. 20.

As shown in FIG. 20, the intensities around the pixel 1/ξ₅ are high. It can be understood that this is because the raised portions of the uneven structure of the polishing surface 2a are tilted in a direction of 90°, and the reflectance in the direction of 90° is increased. In addition, since the raised portions are tilted in the direction of 90°, it can be understood that the uneven structure corresponding to a long spatial wavelength exists in the direction of 90° on the surface of the polishing pad 2. Pixels in the left side of the graphs in FIGS. 18 to 25, where the change in intensity in each irradiating angle is large, correspond to long spatial wavelengths, while pixels in the right side of the graphs, where the change in intensity in each irradiating angle is small, correspond to short spatial wavelengths.

As shown in FIGS. 18 to 25, the measured value of the surface property of the polishing pad 2 (the intensity of reflected light from the polishing pad 2) varies depending on the irradiating direction. Specifically, in order to investigate the relationship between the condition of the polishing pad 2 and polishing performance and to optimize the dressing condition, it is beneficial to obtain information on unevenness in multiple directions instead of information on unevenness in one direction. As in the present embodiment, the surface properties of the polishing pad 2 (intensity distributions of reflected lights from the polishing pad 2) with respect to the plurality of irradiating directions are measured, so that the surface condition of the polishing pad 2 can be evaluated in more detail, and the dressing condition can be optimized. In this embodiment, the irradiating direction of the laser light is changed every 45°, but the changing pitch of the irradiating direction is not limited to this embodiment.

In step 3-3, the irradiating direction of the laser light is set such that the irradiating direction of the laser light emitted by the light source 33 of the light-emitting structure 32 coincides with the irradiating direction determined in the step 3-2, i.e., the irradiating direction that maximizes the intensity of the reflected light from the polishing pad 2 in the specific spatial wavelength region. Specifically, the irradiating-direction changing mechanism 90 adjusts the angles of the light-emitting structure 32 and the light-receiving structure 35 to thereby set the irradiating direction of the laser light. As a result, the irradiating direction of the laser light is optimized for measuring the surface property of the polishing pad 2. The surface property of the polishing pad 2 (intensity distribution of the reflected light from the polishing pad 2) is measured in the optimum irradiating direction. Therefore, the measurement accuracy of the surface property of the polishing pad 2 can be improved, resulting in more precise measurement of the surface property of the polishing pad 2 and optimal dressing condition.

The steps 3-1 to 3-3 (hereinafter referred to as direction setting process) may be performed each time the surface property of the polishing pad 2 is to be measured, or may be performed only once in order to determine the processes of measuring the surface property of the polishing pad. For example, the direction setting process may be performed before measuring of the surface property of the polishing pad 2 in the step 1-2 described with reference to FIG. 9, or may be performed before measuring of the surface property of the polishing pad 2 in the step 2-3 described with reference to FIG. 13.

In step 3-4, the surface property of the polishing pad 2 is measured at multiple points. Specifically, the intensity distributions of the reflected lights from the polishing pad 2 are measured at a plurality of different points on the surface of the polishing pad 2. The process of measuring of the intensity distributions at the multiple points on the surface of the polishing pad 2 is the same as the step 1-2.

In step 3-5, the data processing device 50 calculates an average of the intensity distributions of the plurality of reflected lights acquired at the step 3-4. Specifically, the data processing device 50 calculates an average of intensities at each corresponding pixel of the intensity distributions to thereby determine the average of the intensity distributions of the plurality of reflected lights. Since step 3-6, which will be described later, is performed after the average of the intensity distributions is determined, the index value that indirectly indicates the surface property of the polishing pad 2 can be efficiently calculated.

In step 3-6, the data processing device 50 calculates the index value that indirectly indicates the surface property of the polishing pad 2 from the average of the intensity distributions of the reflected lights from the polishing pad 2. In one embodiment, the index value that indirectly indicates the surface property of the polishing pad 2 is the wavelength composition ratio described above. The data processing device 50 performs Fourier transform on the intensity distribution of the reflected light to convert the intensity distribution of the reflected light into a spatial wavelength spectrum of the surface of the polishing pad 2 and calculates the wavelength composition ratio from the spatial wavelength spectrum. In this manner, the data processing device 50 determines the index value that indirectly indicates the surface property of the polishing pad 2. In one embodiment, in step 3-6, index values each indirectly indicating the surface property of the polishing pad 2 may be calculated from the plurality of intensity distributions, respectively, obtained in the step 3-4. In this case, the step 3-5 is not performed.

In this embodiment, the intensity distributions of the plurality of reflected lights from the polishing pad corresponding to the plurality of lights directed to the polishing pad in different directions can be obtained. As a result, the accuracy of measuring the surface property of the polishing pad 2 can be improved.

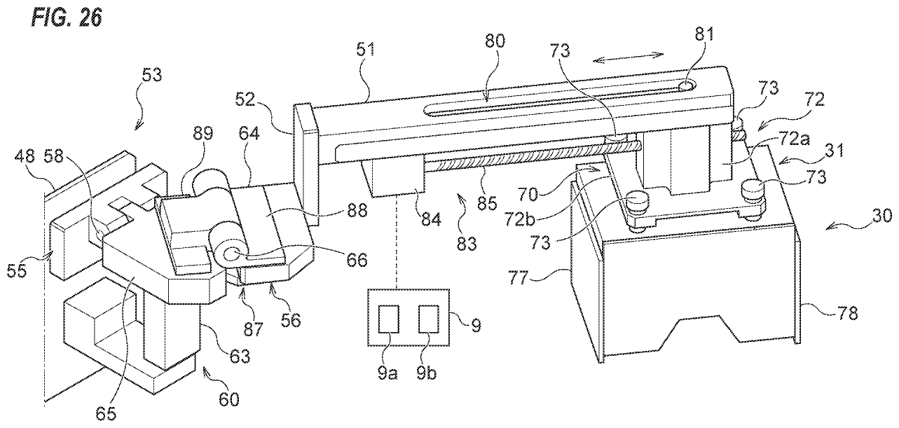

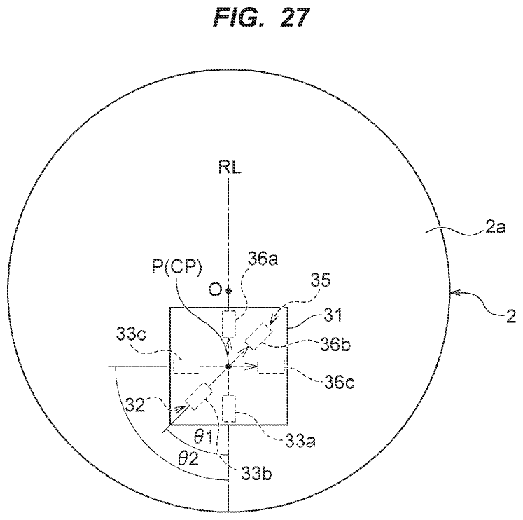

FIG. 26 is a schematic diagram showing still another embodiment of the surface property measuring apparatus 30, and FIG. 27 is a top view of the measuring head 31 shown in FIG. 26. Configurations and operations of the present embodiment, which will not be specifically described, are the same as those of the embodiments described with reference to FIGS. 15 to 17, and repetitive descriptions thereof will be omitted.

The surface property measuring apparatus 30 of this embodiment differs from the embodiment described with reference to FIG. 15 in that it does not include the irradiating-direction changing mechanism 90. In this embodiment, the posture adjusting mechanism 70 is coupled to the measuring head 31, and the adjustment pins 73 are fixed to the upper surface of the measuring head 31, as in the embodiment described with reference to FIG. 8.

As shown in FIG. 27, in this embodiment, the light-emitting structure 32 includes a plurality of light sources 33a, 33b, and 33c facing in different directions, and the light-receiving structure 35 has a plurality of light-receiving elements 36a, 36b, and 36c facing in different directions. Specifically, the light sources 33a, 33b, and 33c are arranged so as to face in different directions as viewed from the polishing-surface-2a side of the polishing pad 2, and the light-receiving elements 36a, 36b, and 36c are arranged so as to face in different directions as viewed from the polishing-surface-2a side of the polishing pad 2. The light sources 33a, 33b, and 33c are arranged so as to irradiate the same position (irradiation position P) with laser lights. The configurations of the light sources 33a, 33b, 33c and the light-receiving elements 36a, 36b, 36c are the same as those of the light source 33 and the light-receiving elements 36. The light-receiving elements 36a, 36b, and 36c face the light sources 33a, 33b, and 33c, respectively, and are configured to receive reflected lights from the polishing pad 2 corresponding to the laser lights emitted by the light sources 33a, 33b, and 33c, respectively.

With such configurations, the light-emitting structure 32 of the present embodiment can irradiate the polishing pad 2 with the lights from different irradiating directions as viewed from the polishing-surface-2a side of the polishing pad 2, and the light-receiving structure 35 receives the reflected lights coming from the surface of the polishing pad 2 in the plurality of directions. In this embodiment, the irradiating angle of the laser light from the light source 33a is 0°, the irradiating angle θ1 of the laser light from the light source 33b is 45°, and the irradiating angle θ2 of the laser light from the light source 33c is 90°. The number and arrangement angles of the light sources are not limited to those of this embodiment. According to this embodiment, the surface properties of the polishing pad 2 (the intensity distributions of the reflected lights from the polishing pad 2) with respect to the plurality of irradiating directions can be measured at one time.

Next, one embodiment of the surface property measuring method for the polishing pad 2 using the surface property measuring apparatus 30 of the present embodiment will be described. The surface property measuring method of this embodiment, which will not be specifically described, is the same as the method described with reference to FIG. 17. In this embodiment, instead of irradiating the polishing pad 2 with the laser light while changing the irradiating direction of the laser light in the step 3-1, the plurality of laser lights in the plurality of irradiating directions are directed to the polishing pad 2 by the plurality of light sources 33a, 33b, and 33c. The plurality of reflected lights from the polishing pad 2 corresponding to the plurality of laser lights directed to the polishing pad 2 are received by the plurality of light-receiving elements 36a, 36b, and 36c, respectively.

In this embodiment, in step 3-3, instead of adjusting the angles (directions) of the light-emitting structure 32 and the light-receiving structure 35 by the irradiating-direction changing mechanism 90, the irradiating direction of the laser light is set by selecting one of the light sources that emits the laser light in an irradiating direction that maximizes the intensity of the reflected light from the polishing pad 2 in a specific spatial wavelength region. In subsequent processes, the selected light source and the light-receiving element facing the selected light source are used to measure the surface property of the polishing pad 2.

In one embodiment, the embodiments described with reference to FIGS. 15 to 25 may be combined with the embodiments described with reference to FIGS. 26 and 27. As a result, the surface properties of the polishing pad 2 (the intensity distributions of the reflected lights from the polishing pad 2) with respect to the plurality of irradiating directions can be measured at one time. Furthermore, the process of changing the irradiating direction of the laser light in the step 3-1 can be shortened.

In one embodiment, a two-dimensional CCD may be used as the light-receiving element 36. Using the two-dimensional CCD as the light-receiving element 36 enables the light-receiving element 36 to receive the reflected light without a need for adjustment even when the laser light is shifted in the horizontal direction.

The above-described embodiments can also be used to determine dressing condition for each substrate processing. The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a surface property measuring apparatus for a polishing pad used for polishing a substrate, such as a semiconductor wafer, a surface property measuring method for a polishing pad, and a surface property judging method for a polishing pad.

### REFERENCE SIGNS LIST

1 polishing table
2 polishing pad
3 table rotating motor
4 table shaft
9 operation controller
10 polishing head
11 polishing-head shaft
12 polishing-head oscillation arm
20 dressing device
21 dresser arm
22 dresser
23 air cylinder
24 dresser shaft
26 support shaft
27 support-shaft rotating motor
30 surface property measuring apparatus
31 measuring head
32 light-emitting structure
33 light source
33a, 33b, 33c light source
35 light-receiving structure
36 light-receiving element
36a, 36b, 36c light-receiving element
38 polarizer
39 ND filter
40 mirror
41 light-reducing filter
43 casing
44 cut
45 nozzle
47a, 47b filter
50 data processing device
51 support artn
52 support plate
53 moving unit
55 fixed block
56 rotating block
58 rotating shaft
60 rotating mechanism
63 cylinder
66 rotating pin
70 posture adjusting mechanism.
72 support base
73 adjustment pin
74 base plate
77, 78 positioning plate
80 elongated hole
81 support shaft
83 measuring-head moving mechanism
84 servomotor
85 ball screw mechanism
87 hinge mechanism
90 irradiating-direction changing mechanism
91 rotating motor
92 shaft
93 angle measuring device

1. A surface property measuring apparatus for a polishing pad used for polishing a substrate, comprising:
a light-emitting structure configured to irradiate the polishing pad with light from a plurality of directions as viewed from a polishing-surface side of the polishing pad; and
a light-receiving structure configured to receive reflected light traveling in a plurality of directions from the surface of the polishing pad.

2. The surface property measuring apparatus according to claim 1, further comprising an irradiating-direction changing mechanism configured to change an irradiating direction of the light.

3. The surface property measuring apparatus according to claim 2, wherein the irradiating-direction changing mechanism comprises a rotating motor configured to rotate the light-emitting structure and the light-receiving structure, and a shaft coupled to the rotating motor.

4. The surface property measuring apparatus according to claim 1, wherein:
the light-emitting structure includes a plurality of light sources facing in different directions; and
the light-receiving structure includes a plurality of light-receiving elements facing in different directions.

5. The surface property measuring apparatus according to claim 1, further comprising a data processing device electrically coupled to the light-receiving structure, the data processing device being configured to determine an index value based on intensity distributions of a plurality of reflected lights from the polishing pad corresponding to a plurality of lights irradiating the polishing pad from different directions, the index value indirectly indicating a surface property of the polishing pad.

6. A surface property measuring method for a polishing pad, comprising:
irradiating the polishing pad with a plurality of lights from different irradiating directions as viewed from a polishing-surface side of the polishing pad;
receiving a plurality of reflected lights from the polishing pad corresponding respectively to the plurality of lights irradiating the polishing pad;
obtaining intensity distributions of the plurality of reflected lights; and
determining an index value based on the intensity distributions, the index value indirectly indicating a surface property of the polishing pad.

7. The surface property measuring method according to claim 6, wherein:
irradiating the polishing pad with the plurality of lights from the different irradiating directions comprises irradiating the polishing pad with light while changing an irradiating direction of the light; and
receiving the plurality of reflected lights from the polishing pad comprises receiving the plurality of reflected lights from the polishing pad corresponding to lights irradiating the polishing pad from different irradiating directions.

8. The surface property measuring method according to claim 6, wherein:
irradiating the polishing pad with the plurality of lights from the different irradiating directions comprises irradiating the polishing pad with the plurality of lights from a plurality of irradiating directions, the plurality of lights being emitted by a plurality of light sources; and
receiving the plurality of reflected lights from the polishing pad comprises receiving, by a plurality of light-receiving elements, the plurality of reflected lights from the polishing pad corresponding to the plurality of lights irradiating the polishing pad from the plurality of irradiating directions.

9. A surface property judging method for a polishing pad, comprising:
irradiating a plurality of points on a surface of the polishing pad with laser light;
receiving a plurality of reflected lights from the surface of the polishing pad;
determining intensity distributions of the plurality of reflected lights at the plurality of points on the surface of the polishing pad;
calculating a wavelength composition ratio from the intensity distributions determined at the plurality of points, the wavelength composition ratio indirectly indicating a surface property of the polishing pad; and
judging whether the surface property of the polishing pad is good or not based on the wavelength composition ratio.

10. The surface property judging method according to claim 9, wherein calculating the wavelength composition ratio from the intensity distributions determined at the plurality of points comprises calculating wavelength composition ratios from the intensity distributions, respectively.

11. The surface property judging method according to claim 9, wherein calculating the wavelength composition ratio from the intensity distributions determined at the plurality of points comprises:
calculating an average of the intensity distributions; and
calculating the wavelength composition ratio from the average of the intensity distributions.

12. The surface property judging method according to claim 10, wherein judging whether the surface property of the polishing pad is good or not based on the wavelength composition ratio comprises:
determining whether the wavelength composition ratios are within a predetermined reference range; and
judging that the surface property of the polishing pad is good when all of the wavelength composition ratios are within the predetermined reference range.

13. The surface property judging method according to claim 10, wherein judging whether the surface property of the polishing pad is good or not based on the wavelength composition ratio comprises:
calculating an average of the wavelength composition ratios;
comparing the average with a predetermined threshold value;
determining whether the wavelength composition ratios are within a predetermined reference range; and
judging that the surface property of the polishing pad is good when the average is smaller than the threshold value and all of the wavelength composition ratios are within the predetermined reference range.

14. The surface property judging method according to claim 10, wherein judging whether the surface property of the polishing pad is good or not based on the wavelength composition ratio comprises:
calculating an average of the wavelength composition ratios;
comparing the average with a predetermined threshold value;
determining whether the wavelength composition ratios are within a predetermined reference range; and
judging that the surface property of the polishing pad is good when the average is larger than the threshold value and all of the wavelength composition ratios are within the predetermined reference range.

15. The surface property judging method according to claim 9, further comprising terminating a break-in process of the polishing pad when the surface property of the polishing pad is determined to be good.
